(19) United States
(12) Patent Application Publication
(10) Pub. No.: US 2026/0290645 A1
(43) Pub. Date: Sep. 24, 2026

(54) CURRENT-CARRYING WIRE, POWER CORD, ELECTRICAL CONNECTION DEVICE, AND ELECTRICAL DEVICE

(71) Applicant: GD MIDEA AIR-CONDITIONING EQUIPMENT CO., LTD., Foshan (CN)

(72) Inventors: Huake WANG, Foshan (CN); Liwei NIU, Foshan (CN)

(21) Appl. No.: 19/684,162

(22) Filed: May 21, 2026

Related U.S. Application Data
(63) Continuation of application No. PCT/CN2024/077770, filed on Feb. 20, 2024.

(30) Foreign Application Priority Data
Nov. 29, 2023 (CN) 202311621145.9
Nov. 29, 2023 (CN) 202323248090.X

(51) Int. Cl. H01B 7/18; H01R 13/713; H01R 24/30; H01R 103/00

(52) U.S. Cl. CPC H01B 7/1855; H01B 7/1805; H01R 13/713; H01R 24/30; H01R 2103/00

(57) ABSTRACT

A current-carrying wire includes a current-carrying conductor, a first insulation layer wrapping the current-carrying conductor, a shielding conductor structure configured to detect a leakage current from the current-carrying conductor, and a second insulation layer, wrapping the shielding conductor structure. The shielding conductor structure includes a shield layer wrapping the first insulation layer.

### CROSS-REFERENCE TO RELATED APPLICATIONS

This application is a continuation of International Application No. PCT/CN2024/077770, filed on Feb. 20, 2024, which claims priority to Chinese Patent Application No. 202311621145.9, filed on Nov. 29, 2023 and entitled “CURRENT-CARRYING WIRE, POWER CORD, ELECTRICAL CONNECTION DEVICE, AND ELECTRICAL DEVICE,” and Chinese Patent Application No. 202323248090.X, filed on Nov. 29, 2023 and entitled “CURRENT-CARRYING WIRE, POWER CORD, ELECTRICAL CONNECTION DEVICE, AND ELECTRICAL DEVICE,” the entire contents of all of which are incorporated herein by reference for all purposes.

### TECHNICAL FIELD

The present disclosure relates to the technical field of power cables, and in particular, to a current-carrying wire, a power cord, an electrical connection device, and an electrical device.

### BACKGROUND

A leakage circuit detector interrupter (LCDI) is a power supply connection device for electrical appliances that monitors leakage current in a power cord assembly through dedicated leakage current detection conductors. When a specified level of leakage current is detected, the LCDI interrupts the electrical connection to the electrical appliances to ensure safe operation. In recent years, in addition to monitoring leakage current along the power cord, LCDI devices have been required to meet more advanced safety demands—for instance, the capability to detect whether the leakage current detection conductor itself is in an open-circuit condition.

Therefore, leakage current detection wires in power cords for use with such LCDIs also need to meet the requirements of safety detection including both leakage detection and open-circuit detection. However, conventional power cord structures do not fully satisfy these safety detection requirements, resulting in poor safety performance during use.

### SUMMARY

To this end, the present disclosure aims to at least partially solve one of the technical problems in the related art and provide a current-carrying wire, a power cord, an electrical connection device, and an electrical device.

In accordance with a first aspect of the present disclosure, an embodiment provides a current-carrying wire, including a first current-carrying conductor, a first insulation layer, a first shielding conductor structure, and a second insulation layer, where:
the first insulation layer wraps the first current-carrying conductor;
the first shielding conductor structure is configured to detect a leakage current from the first current-carrying conductor, the first shielding conductor structure includes a first shield layer wrapping the first insulation layer and a first conductor in direct contact with the first shield layer, and the first conductor is configured to transmit an electrical signal from the first shielding conductor structure to the outside of the current-carrying wire; and
the second insulation layer wraps an outer side of the first shielding conductor structure.

In the current-carrying wire according to some embodiments of the present disclosure, the first shielding conductor structure has a first terminal adjacent to an input end of the first current-carrying conductor, a second terminal adjacent to an output end of the first current-carrying conductor, and a third terminal disposed between the first terminal and the second terminal, the current-carrying wire further includes a first metal conductor led out from the third terminal, and the second insulation layer has a first opening where the first metal conductor passes through.

In the current-carrying wire according to some embodiments of the present disclosure, an insulation cover is arranged at outside of the first metal conductor.

In the current-carrying wire according to some embodiments of the present disclosure, the first shield layer is made of a single-sided-conductive flexible material; and the first shield layer is helically wound to wrap the first insulation layer, or wraps the first insulation layer in a direction parallel to an axial direction of the first current-carrying conductor.

In the current-carrying wire according to some embodiments of the present disclosure, the first shield layer is a mesh woven from a plurality of strands of conductors to wrap the first insulation layer.

In the current-carrying wire according to some embodiments of the present disclosure, the first shield layer includes a shield layer made of a single-sided-conductive flexible material and a shield layer which is a mesh woven from a plurality of strands of conductors.

In the current-carrying wire according to some embodiments of the present disclosure, the first conductor is located between the first insulation layer and the first shield layer, or located between the first shield layer and the second insulation layer.

In accordance with the first aspect of the present disclosure, another embodiment provides a current-carrying wire, including a first current-carrying conductor, a first insulation layer, a first shielding conductor structure, a second insulation layer, and a first metal conductor, where:
the first insulation layer wraps the first current-carrying conductor;
the first shielding conductor structure is configured to detect a leakage current from the first current-carrying conductor, the first shielding conductor structure includes a first shield layer wrapping the first insulation layer, and the first shielding conductor structure has a first terminal adjacent to an input end of the first current-carrying conductor, a second terminal adjacent to an output end of the first current-carrying conductor, and a third terminal disposed between the first terminal and the second terminal;
the second insulation layer wraps an outer side of the first shielding conductor structure; and
the first metal conductor is led out from the third terminal, and the second insulation layer has a first opening where the first metal conductor passes through.

In accordance with the first aspect of the present disclosure, another embodiment provides a current-carrying wire, including a first current-carrying conductor, a first insulation layer, a first shielding conductor structure, and a second insulation layer, where:
the first insulation layer wraps the first current-carrying conductor;
the first shielding conductor structure is configured to detect a leakage current from the first current-carrying conductor, the first shielding conductor structure includes a first shield layer wrapping the first insulation layer, a second shield layer wrapping the first shield layer, and a first conductor located between the first shield layer and the second shield layer, and the first conductor is configured to transmit an electrical signal from the first shielding conductor structure to the outside of the current-carrying wire; and
the second insulation layer wraps an outer side of the first shielding conductor structure.

In the current-carrying wire according to some embodiments of the present disclosure, the first shielding conductor structure has a first terminal adjacent to an input end of the first current-carrying conductor, a second terminal adjacent to an output end of the first current-carrying conductor, and a third terminal disposed between the first terminal and the second terminal, the current-carrying wire further includes a first metal conductor led out from the third terminal, and the second insulation layer has a first opening where the first metal conductor passes through.

In the current-carrying wire according to some embodiments of the present disclosure, an insulation cover is arranged at outside of the first metal conductor.

In the current-carrying wire according to some embodiments of the present disclosure, the first shield layer is made of a single-sided-conductive flexible material, the first shield layer has an insulation surface facing inward and in contact with a surface of an outer side of the first insulation layer, and a conductive surface facing outward and in contact with the first conductor and the second shield layer; and the second shield layer is a mesh woven from a plurality of strands of conductors to wrap the first shield layer.

In the current-carrying wire according to some embodiments of the present disclosure, the first shield layer is a mesh woven from a plurality of strands of conductors to wrap the first insulation layer; and the second shield layer is made of a single-sided-conductive flexible material, the second shield layer has a conductive surface facing inward and in contact with the first conductor and the first shield layer, and the insulation surface facing outward and in contact with a surface of an inner side of the second insulation layer.

In the current-carrying wire according to some embodiments of the present disclosure, the first conductor is a single-strand wire or a multi-strand wire; and the first conductor is helically wound to wrap an outer side of the first insulation layer, or is arranged at the outer side of the first insulation layer in a direction parallel to an axial direction of the first current-carrying conductor.

In the current-carrying wire according to some embodiments of the present disclosure, the second insulation layer is made of a flexible insulation film material, and winds around the first shielding conductor structure or wraps on the first shielding conductor structure in a direction parallel to an axial direction of the first current-carrying conductor; or
the second insulation layer is an injection-molded insulation cover.

In accordance with a second aspect of the present disclosure, an embodiment provides a power cord, including a first current-carrying wire and a second current-carrying wire, where:
the first current-carrying wire includes a first current-carrying conductor, a first insulation layer wrapping the first current-carrying conductor, and a first shielding conductor structure, the first shielding conductor structure is configured to detect a leakage current from the first current-carrying conductor, the first shielding conductor structure includes a first shield layer wrapping the first insulation layer, and the first shielding conductor structure has a first terminal adjacent to an input end of the power cord, a second terminal adjacent to an output end of the power cord, and a third terminal disposed between the first terminal and the second terminal;
the second current-carrying wire includes a second current-carrying conductor, a third insulation layer wrapping the second current-carrying conductor, and a second shielding conductor structure, the second shielding conductor structure is configured to detect a leakage current from the second current-carrying conductor, the second shielding conductor structure includes a third shield layer wrapping the third insulation layer, and the second shielding conductor structure includes a fourth terminal adjacent to the input end, a fifth terminal adjacent to the output end, and a sixth terminal disposed between the fourth terminal and the fifth terminal; and
the fifth insulation layer encloses the first current-carrying wire and the second current-carrying wire;
where the first shielding conductor structure and the second shielding conductor structure are separated from each other in the fifth insulation layer, so that the first shielding conductor structure is insulated from the second shielding conductor structure; and
the first current-carrying wire and the second current-carrying wire further satisfy any one of the following four cases:
case one: the first current-carrying wire further includes a first metal conductor led out from the third terminal, and the first metal conductor is connected to the sixth terminal;
case two: the second current-carrying wire further includes a second metal conductor led out from the sixth terminal, and the second metal conductor is connected to the third terminal;
case three: the first current-carrying wire further includes a first metal conductor led out from the third terminal, the second current-carrying wire further includes a second metal conductor led out from the sixth terminal, and the first metal conductor is connected to the second metal conductor; and
case four: the power cord further includes a third metal conductor, and two terminals of the third metal conductor are respectively connected to the third terminal and the sixth terminal.

It can also be understood that the first shielding conductor structure and the second shielding conductor structure are separated from each other in the fifth insulation layer, so that the first shielding conductor structure is insulated from the second shielding conductor structure, thereby preventing leakage detection of the first current-carrying wire and leakage detection of the second current-carrying wire from interfering with each other.

In accordance with a second aspect of the present disclosure, another embodiment provides a power cord, including a first current-carrying wire, a second current-carrying wire and a fifth insulation layer, where:
the first current-carrying wire includes a first current-carrying conductor, a first insulation layer wrapping the first current-carrying conductor, and a first shielding conductor structure, the first shielding conductor structure is configured to detect a leakage current from the first current-carrying conductor, the first shielding conductor structure includes a first shield layer wrapping the first insulation layer and a first conductor in direct contact with the first shield layer, and the first conductor is configured to transmit an electrical signal from the first shielding conductor structure to outside of the current-carrying wire;
the second current-carrying wire includes a second current-carrying conductor, a third insulation layer wrapping the second current-carrying conductor, and a second shielding conductor structure, the second shielding conductor structure is configured to detect a leakage current from the second current-carrying conductor, the second shielding conductor structure includes a third shield layer wrapping the third insulation layer and a second conductor in direct contact with the third shield layer, and the second conductor is configured to transmit an electrical signal from the second shielding conductor structure to outside of the current-carrying wire;
the fifth insulation layer encloses the first current-carrying wire and the second current-carrying wire; and
the first shielding conductor structure and the second shielding conductor structure are separated from each other in the fifth insulation layer, so that the first shielding conductor structure is insulated from the second shielding conductor structure.

In the power cord according to some embodiments of the present disclosure, the first current-carrying wire further includes a second insulation layer wrapping the first shielding conductor structure, and/or the second current-carrying wire further includes a fourth insulation layer wrapping the second shielding conductor structure.

In the power cord according to some embodiments of the present disclosure, space in the fifth insulation layer not occupied by the first current-carrying wire and the second current-carrying wire is filled with an insulation material.

In the power cord according to some embodiments of the present disclosure, the first shielding conductor structure has a first terminal adjacent to an input end of the power cord, a second terminal adjacent to an output end of the power cord, and a third terminal disposed between the first terminal and the second terminal; the second shielding conductor structure includes a fourth terminal adjacent to the input end, a fifth terminal adjacent to the output end, and a sixth terminal disposed between the fourth terminal and the fifth terminal; and
the first current-carrying wire and the second current-carrying wire further satisfy any one of the following four cases:
case one: the first current-carrying wire further includes a first metal conductor led out from the third terminal, and the first metal conductor is connected to the sixth terminal;
case two: the second current-carrying wire further includes a second metal conductor led out from the sixth terminal, and the second metal conductor is connected to the third terminal;
case three: the first current-carrying wire further includes a first metal conductor led out from the third terminal, the second current-carrying wire further includes a second metal conductor led out from the sixth terminal, and the first metal conductor is connected to the second metal conductor; and
case four: the power cord further includes a third metal conductor, and two terminals of the third metal conductor are respectively connected to the third terminal and the sixth terminal.

In the power cord according to some embodiments of the present disclosure, in the presence of the second insulation layer, the second insulation layer has a first opening the first metal conductor passes through; and in the presence of the fourth insulation layer, the fourth insulation layer is provided with a second opening where the second metal conductor passes through.

In the power cord according to some embodiments of the present disclosure, an insulation cover is respectively arranged at outside of the first metal conductor and outside of the second metal conductor.

In the power cord according to some embodiments of the present disclosure, in the case one, the first metal conductor is soldered to the sixth terminal; in the case two, the second metal conductor is soldered to the third terminal; in the case three, the first metal conductor and the second metal conductor are electrically connected by soldering at a position between the third terminal and the sixth terminal; and in the case four, one end of the third metal conductor is soldered to the third terminal, and the other end of the third metal conductor is soldered to the sixth terminal.

In the power cord according to some embodiments of the present disclosure, the first metal conductor and the second metal conductor extend to a position adjacent to the input end or extend to a position adjacent to the output end to achieve an electrical connection.

In the power cord according to some embodiments of the present disclosure, the first conductor and the second conductor are each a multi-strand wire, the first metal conductor is formed by at least one strand in the first conductor led out from the third terminal, and the second metal conductor is formed by at least one strand in the second conductor led out from the sixth terminal.

In the power cord according to some embodiments of the present disclosure, the first shield layer is a mesh woven from a plurality of strands of conductors to wrap the first insulation layer, the third shield layer is a mesh woven from a plurality of strands of conductors to wrap the third insulation layer, the first metal conductor is formed by at least one strand of conductor in the first shield layer led out from the third terminal, and the second metal conductor is formed by at least one strand of conductor in the third shield layer led out from the sixth terminal.

In the power cord according to some embodiments of the present disclosure, the third shield layer is made of a single-sided-conductive flexible material; and the third shield layer is helically wound to wrap the third insulation layer, or wraps the third insulation layer in a direction parallel to an axial direction of the second current-carrying conductor.

In the power cord according to some embodiments of the present disclosure, the third shield layer is a mesh woven from a plurality of strands of conductors to wrap the third insulation layer.

In the power cord according to some embodiments of the present disclosure, the third shield layer includes a shield layer made of a single-sided-conductive flexible material and a shield layer which is a mesh woven from a plurality of strands of conductors.

In the power cord according to some embodiments of the present disclosure, the second conductor is located between the third insulation layer and the third shield layer, or in the presence of the fourth insulation layer, is located between the third shield layer and the fourth insulation layer.

In the power cord according to some embodiments of the present disclosure, the second shielding conductor structure further includes a fourth shield layer wrapping the third shield layer and the second conductor, and the second conductor is located between the third shield layer and the fourth shield layer.

In the power cord according to some embodiments of the present disclosure, the third shield layer is made of a single-sided-conductive flexible material, the third shield layer has an insulation surface facing inward and in contact with a surface of an outer side of the third insulation layer, and a conductive surface of facing outward and in contact with the second conductor and the fourth shield layer; and the fourth shield layer is a mesh woven from a plurality of strands of conductors to wrap the third shield layer.

In the power cord according to some embodiments of the present disclosure, the third shield layer is a mesh woven from a plurality of strands of conductors to wrap the third insulation layer; the fourth shield layer is made of a single-sided-conductive flexible material, and the fourth shield layer has a conductive surface facing inward and in contact with the second conductor and the third shield layer, and in the presence of the fourth insulation layer, an insulation surface of the fourth shield layer faces outward and is in contact with a surface of an inner side of the fourth insulation layer.

In the power cord according to some embodiments of the present disclosure, the second conductor is helically wound to wrap an outer side of the third insulation layer, or is arranged at the outer side of the third insulation layer in a direction parallel to an axial direction of the second current-carrying conductor.

In the power cord according to some embodiments of the present disclosure, the fourth insulation layer is made of a flexible insulation film material, and winds around the second shielding conductor structure or wraps on the second shielding conductor structure in a direction parallel to an axial direction of the second current-carrying conductor; or
the fourth insulation layer is an injection-molded insulation cover.

In the power cord according to some embodiments of the present disclosure, the power cord further includes a first return wire and a second return wire located in the fifth insulation layer, where one end of the first return wire adjacent to the output end is connected to the second terminal, and one end of the second return wire adjacent to the output end is connected to the fifth terminal.

In the power cord according to some embodiments of the present disclosure, the first shielding conductor structure further includes a second shield layer wrapping the first shield layer and the first conductor, and the first conductor is located between the first shield layer and the second shield layer; and the second shielding conductor structure further includes a fourth shield layer wrapping the third shield layer and the second conductor, and the second conductor is located between the third shield layer and the fourth shield layer.

In the power cord according to some embodiments of the present disclosure, the first shield layer is made of a single-sided-conductive flexible material, the first shield layer has an insulation surface facing inward and in contact with a surface of an outer side of the first insulation layer, and a conductive surface facing outward and in contact with the first conductor and the second shield layer; the second shield layer is a mesh woven from a plurality of strands of conductors to wrap the first shield layer; the third shield layer is made of a single-sided-conductive flexible material, the third shield layer has an insulation surface facing inward and in contact with a surface of an outer side of the third insulation layer, and a conductive surface facing outward and in contact with the second conductor and the fourth shield layer; and the fourth shield layer is a mesh woven from a plurality of strands of conductors to wrap the third shield layer.

In the power cord according to some embodiments of the present disclosure, the first return wire is located outside the first current-carrying wire, or between the second insulation layer and the first shielding conductor structure, or in the first shielding conductor structure, or between the first shielding conductor structure and the first insulation layer.

In the power cord according to some embodiments of the present disclosure, the second return wire is located outside the second current-carrying wire, or between the fourth insulation layer and the second shielding conductor structure, or in the second shielding conductor structure, or between the second shielding conductor structure and the third insulation layer.

In the power cord according to some embodiments of the present disclosure, one end of the first shield layer adjacent to the output end, one end of the first conductor adjacent to the output end, or one end of the second shield layer adjacent to the output end serves as the second terminal and is connected to one end of the first return wire adjacent to the output end.

In the power cord according to some embodiments of the present disclosure, one end of the third shield layer adjacent to the output end, one end of the second conductor adjacent to the output end, or one end of the fourth shield layer adjacent to the output end serves as the fifth terminal and is connected to one end of the second return wire adjacent to the output end.

In the power cord according to some embodiments of the present disclosure, the first return wire and the second return wire are each a lead wire having an insulation cover.

In accordance with a third aspect of the present disclosure, an embodiment provides an electrical connection device, including a housing, a detection protection device arranged in the housing, and the power cord of any one of the embodiments of the second aspect, where the first current-carrying conductor, the second current-carrying conductor, the first terminal, the second terminal, the fourth terminal, and the fifth terminal are connected to the detection protection device, the first terminal and the fourth terminal are located in the housing, and the third terminal and the sixth terminal are located at a position where the power cord is connected to the housing.

In accordance with the third aspect of the present disclosure, another embodiment provides an electrical connection device, including a housing, a detection protection device arranged in the housing, and the power cord of any one of the embodiments of the second aspect, where the first current-carrying conductor, the second current-carrying conductor, the first terminal, the second terminal, the fourth terminal, and the fifth terminal are connected to the detection protection device, the first terminal and the fourth terminal are located in the housing, an output end of the power cord is configured to connect to a load device, and the third terminal and the sixth terminal are located at a position where the power cord is connected to the load device.

In accordance with the third aspect of the present disclosure, another embodiment provides an electrical connection device, including a housing, a detection protection device arranged in the housing, and the power cord of any one of the embodiments of the second aspect, where the first current-carrying conductor, the second current-carrying conductor, the first terminal, the second terminal, the fourth terminal, and the fifth terminal are connected to the detection protection device, the first terminal and the fourth terminal are located in the housing, an output end of the power cord is configured to connect to a load device, and the third terminal and the sixth terminal are located between the housing and the load device.

In the electrical connection device according to some embodiments of the present disclosure, a clip configured to secure the power cord is arranged at a position where the power cord is connected to the housing.

In the electrical connection device according to some embodiments of the present disclosure, the detection protection device includes:
a switch, configured to control a power connection between an input end and an output end of the power cord; and
a driver, respectively connected to the first current-carrying conductor, the second current-carrying conductor, the first terminal, the second terminal, the fourth terminal, the fifth terminal, and the switch, and configured to control the switch to interrupt the power connection when a leakage current or an open circuit occurs in the first shielding conductor structure and/or a leakage current or an open circuit occurs in the second shielding conductor structure.

In accordance with a fourth aspect of the present disclosure, an embodiment provides an electrical device, including a load device and the electrical connection device of any one of the embodiments of the third aspect, where an output end of the power cord is connected to the load device.

Additional features and advantages of the present disclosure will be set forth in the description which follows, and in part will be obvious from the description, or may be learned by the practice of the present disclosure. The other advantages of the present disclosure can be realized and obtained by the structures particularly pointed out in the description, claims and drawings.

### BRIEF DESCRIPTION OF DRAWINGS

The drawings are provided for a further understanding of the technical schemes of the present disclosure, and constitute a part of the description. The drawings and the embodiments of the present disclosure are used to explain the technical schemes of the present disclosure, but are not intended to limit the technical schemes of the present disclosure.

The present disclosure will be further described below with reference to the accompanying drawings and embodiments.

FIG. 1 is a schematic structural cross-sectional view of a current-carrying wire according to an embodiment of the present disclosure;

FIG. 2 is a schematic structural side view of a current-carrying wire according to an embodiment of the present disclosure;

FIG. 3 is a schematic structural side view of a current-carrying wire according to an embodiment of the present disclosure;

FIG. 4 is a schematic structural cross-sectional view of a current-carrying wire according to an embodiment of the present disclosure;

FIG. 5 is a schematic structural cross-sectional view of a current-carrying wire according to an embodiment of the present disclosure;

FIG. 6 is a schematic structural side view of a current-carrying wire according to an embodiment of the present disclosure;

FIG. 7 is a schematic structural cross-sectional view of a power cord according to an embodiment of the present disclosure;

FIG. 8 is a schematic structural side view of a power cord according to an embodiment of the present disclosure;

FIG. 9A is a schematic structural side view of a power cord according to an embodiment of the present disclosure;

FIG. 9B is a schematic structural side view of a power cord according to an embodiment of the present disclosure;

FIG. 9C is a schematic structural side view of a power cord according to an embodiment of the present disclosure;

FIG. 9D is a schematic structural side view of a power cord according to an embodiment of the present disclosure;

FIG. 10 is a schematic structural side view of a power cord according to an embodiment of the present disclosure;

FIG. 11 is a schematic structural cross-sectional view of a power cord according to an embodiment of the present disclosure;

FIG. 12 is a schematic structural side view of a power cord according to an embodiment of the present disclosure;

FIG. 13 is a schematic structural diagram of an electrical connection device according to an embodiment of the present disclosure; and

FIG. 14 is a schematic diagram illustrating a circuit connection between a detection protection device and a power cord in an electrical connection device according to an embodiment of the present disclosure.

### DETAILED DESCRIPTION

Embodiments of the present disclosure are described in detail below, examples of which are illustrated in the accompanying drawings. The function of the accompanying drawings is to supplement the description of the text part of the description with graphics, such that those having ordinary skills in the art can intuitively and vividly understand each technical feature and the overall technical scheme of the present disclosure, but the accompanying drawings are not intended to be construed as limiting the scope of the present disclosure.

In the description of the present disclosure, “several” means one or more, “multiple (plurality of)” means two or more, “greater than,” “less than,” “exceeding,” and the like are understood as excluding the given number, while “above,” “below,” “within,” and the like are understood as including the given number. “At least one” means one or more, and the expression “at least one of the following . . . ” and similar expressions refer to any combination of the items, including any combination of a single item or a plurality of items. Any reference to “first,” “second,” and the like is used merely for distinguishing technical features and should not be construed as indicating or implying relative importance, implicitly indicating the number of the indicated technical features, or implicitly indicating the order of precedence of the indicated technical features.

In the description of the present disclosure, unless otherwise expressly limited, terms such as “arranged,” “mounted,” “connected,” and the like should be understood in a broad sense. A person skilled in the art can reasonably determine the specific meanings of these terms in the present disclosure based on the specific context of the technical schemes. For example, the term “connected” may refer to a mechanical connection, an electrical connection, or a connection enabling communication with each other; it may be a direct connection, or an indirect connection via an intermediate medium.

It should be noted that the technical features involved in the various embodiments of the present disclosure described below may be combined with each other if not in conflict.

A leakage circuit detector interrupter (LCDI) is a power supply connection device for electrical appliances that monitors leakage current in a power cord assembly through dedicated leakage current detection conductors. When a specified level of leakage current is detected, the LCDI interrupts the electrical connection to the electrical appliances to ensure safe operation. In recent years, in addition to monitoring leakage current along the power cord, LCDI devices have been required to meet more advanced safety demands—for instance, the capability to detect whether the leakage current detection conductor itself is in an open-circuit condition. Therefore, leakage current detection wires in power cords for use with such LCDIs also need to meet the requirements of safety detection including both leakage detection and open-circuit detection. However, conventional power cord structures do not fully satisfy these safety detection requirements, resulting in poor safety performance during use. In view of the above, embodiments of the present disclosure provide a current-carrying wire, a power cord, an electrical connection device, and an electrical device, which can improve the power supply safety.

The embodiments of the present disclosure will be further described in detail below with reference to the accompanying drawings.

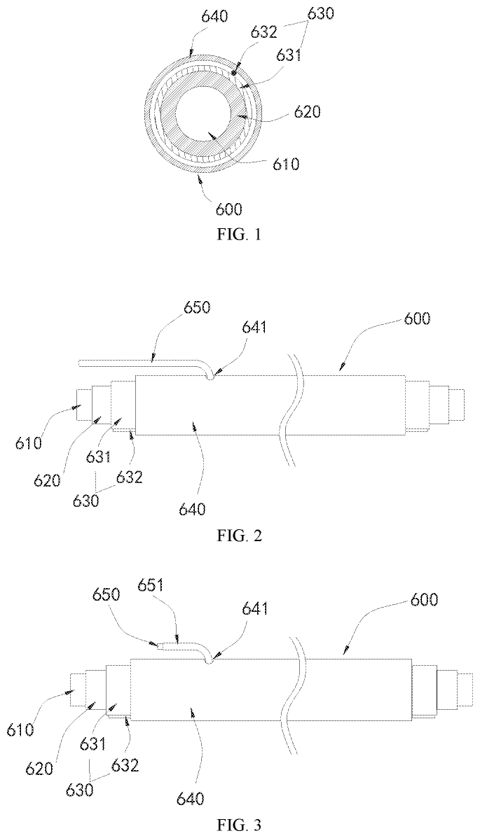

Referring to FIG. 1 and FIG. 2, in accordance with a first aspect of the present disclosure, an embodiment provides a current-carrying wire 600, which includes a first current-carrying conductor 610, a first insulation layer 620, a first shielding conductor structure 630, and a second insulation layer 640.

The first insulation layer 620 wraps the first current-carrying conductor 610.

The first shielding conductor structure 630 is configured to detect a leakage current from the first current-carrying conductor 610. The first shielding conductor structure 630 includes a first shield layer 631 wrapping the first insulation layer 620 and a first conductor 632 in direct contact with the first shield layer 631. The first conductor 632 is configured to transmit an electrical signal from the first shielding conductor structure 630 to outside of the current-carrying wire 600.

The second insulation layer 640 wraps an outer side of the first shielding conductor structure 630.

In the current-carrying wire 600 of the embodiment, the first current-carrying conductor 610 is configured to supply an operating current to a load device. The first insulation layer 620 wraps the first current-carrying conductor 610 to avoid leakage. The first shielding conductor structure 630 arranged at an outer side of the first insulation layer 620 can effectively detect a possible leakage situation and transmit a signal to the outside of the current-carrying wire 600 to cut off the power supply when the first insulation layer 620 is damaged, thereby preventing accidental electric shocks to personnel and improving safety. The first shielding conductor structure 630 includes a first shield layer 631 and a first conductor 632. The first shield layer 631 wraps the first current-carrying conductor 610 to comprehensively detect a leakage current on the entire first current-carrying conductor 610. The first conductor 632 in direct contact with the first shield layer 631 can conveniently and reliably transmit an electrical signal from the first shielding conductor structure 630 to outside of the current-carrying wire 600. In addition, the second insulation layer 640 is further used to wrap the first shielding conductor structure 630, to achieve a closer contact between the first shield layer 631 and the first conductor 632, so that the electrical signal on the first shield layer 631 can be more reliably transmitted to the first conductor 632. Therefore, the first shielding conductor structure 630 composed of the first shield layer 631 and the first conductor 632 has the advantages of comprehensive detection and convenient and reliable electrical signal transmission, thereby improving the power supply safety of the current-carrying wire 600.

Referring to FIG. 2, in the current-carrying wire 600 according to some embodiments of the present disclosure, the first shielding conductor structure 630 has a first terminal adjacent to an input end of the first current-carrying conductor 610, a second terminal adjacent to an output end of the first current-carrying conductor 610, and a third terminal disposed between the first terminal and the second terminal, the current-carrying wire 600 further includes a first metal conductor 650 led out from the third terminal, and the second insulation layer 640 has a first opening 641 configured for the first metal conductor 650 to pass through.

It shall be understood that, taking a placement direction of the current-carrying wire 600 shown in FIG. 2 as an example, if the left end of the current-carrying wire 600 is used for connecting to a plug for supplying power and the right end of the current-carrying wire 600 is used for connecting to a load device, the first terminal of the first shielding conductor structure 630 is located on the left side shown in FIG. 2, the second terminal of the first shielding conductor structure 630 is located on the right side shown in FIG. 2, and the third terminal is located between the first terminal and the second terminal, for example, on an inner side of the first opening 641 shown in FIG. 2.

In this embodiment, the first metal conductor 650 led out from the third terminal can transmit an electrical signal on the first shielding conductor structure 630 from the third terminal to outside of the current-carrying wire 600, so that the first shielding conductor structure 630 can transmit an electrical signal from the first terminal on the left side to the outside of the current-carrying wire 600, transmit an electrical signal from the second terminal on the right side to the outside of the current-carrying wire 600, or transmit an electrical signal from the third terminal in the middle to the outside of the current-carrying wire 600. As such, leakage detection of the current-carrying wire 600 can be realized at different positions. Furthermore, the first shielding conductor structure 630 may be divided into two segments, the first segment being located between the first terminal on the left side and the third terminal in the middle, and the second segment being located between the third terminal in the middle and the second terminal on the right side, so that a disconnection detection can be performed for the two segments respectively, thereby meeting various requirements for safety detection of the current-carrying wire 600.

In addition, the second insulation layer 640 has the first opening 641 for the first metal conductor 650 to pass through, i.e., the second insulation layer 640 is broken at the first opening 641, and the integrity of the second insulation layer 640 is guaranteed as much as possible at other positions, so as to prevent a reduction in the protective effect of the second insulation layer 640 on the first current-carrying conductor 610 and the first shielding conductor structure 630.

Referring to FIG. 3, in the current-carrying wire 600 according to some embodiments of the present disclosure, an insulation cover 651 is arranged at outside of the first metal conductor 650. It shall be understood that the structure of the current-carrying wire 600 in the embodiment shown in FIG. 3 is the same as the structure of the current-carrying wire 600 in the embodiment shown in FIG. 2, except that the insulation cover 651 arranged at outside of the first metal conductor 650 is additionally provided.

In this embodiment, the insulation cover 651 is additionally provided to protect the first metal conductor 650, which not only can prevent an electrical signal transmitted on the first metal conductor 650 from other interference, but also can prevent the first metal conductor 650 from being easily broken by an external force.

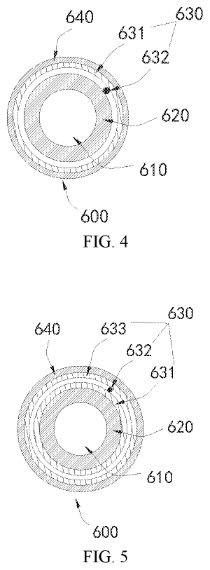

In the current-carrying wire 600 according to some embodiments of the present disclosure, the first conductor 632 is located between the first insulation layer 620 and the first shield layer 631, for example, as shown in FIG. 4; or the first conductor 632 is located between the first shield layer 631 and the second insulation layer 640, for example, as shown in FIG. 1.

It shall be understood that in this embodiment, the relative positions of the first shield layer 631 and the first conductor 632 that constitute the first shielding conductor structure 630 can be interchanged, as long as it can be ensured that the first shield layer 631 and the first conductor 632 are in direct contact with each other and have a reliable electrical connection relationship to ensure the stability of electrical signal transmission.

In the current-carrying wire 600 according to some embodiments of the present disclosure, the first shield layer 631 is made of a single-sided-conductive flexible material; and the first shield layer 631 is helically wound to wrap the first insulation layer 620, or wraps the first insulation layer 620 in a direction parallel to an axial direction of the first current-carrying conductor 610.

The single-sided-conductive flexible material has two surfaces: an insulation surface and a conductive surface. Therefore, in order to ensure a reliable electrical connection relationship between the first shield layer 631 and the first conductor 632, the conductive surface of the first shield layer 631 needs to be arranged facing the first conductor 632. For example, in the embodiment shown in FIG. 1 where the first conductor 632 is located between the first shield layer 631 and the second insulation layer 640, the insulation surface of the first shield layer 631 faces inward and wraps the first insulation layer 620, and the conductive surface of the first shield layer 631 faces outward and is contact with the first conductor 632; and in the embodiment shown in FIG. 4 where the first conductor 632 is located between the first insulation layer 620 and the first shield layer 631, the conductive surface of the first shield layer 631 faces inward and wraps both the first insulation layer 620 and the first conductor 632, so that the conductive surface of the first shield layer 631 is in reliable contact with the first conductor 632.

In the current-carrying wire 600 according to some embodiments of the present disclosure, the first shield layer 631 is a mesh woven from a plurality of strands of conductors to wrap the first insulation layer 620.

Compared with the above embodiments in which a single-sided-conductive flexible material is used as the first shield layer 631, this embodiment provides a first shield layer 631 made of a different material, i.e., uses a mesh woven from a plurality of strands of conductors as the first shield layer 631. In this way, at least one strand of conductor may be pulled out from the first shield layer 631 and passes through the first opening 641 to serve as the first metal conductor 650. That is, when the first metal conductor 650 need to be led out from the third terminal, it is only necessary to cut a first opening 641 in the second insulation layer 640 and then pull out at least one strand of conductor from the first shield layer 631 which is a mesh woven from a plurality of strands of conductors.

It shall be noted that because the first conductor 632 may be a single-strand wire or a multi-strand wire, the first metal conductor 650 may be at least one strand of conductor of the first conductor 632 which is pulled out from the first opening 641.

It shall be understood that in an embodiment, the first conductor 632 is a tin wire. Because the current-carrying wire 600 is generally connected to a printed circuit board (PCB), an electrical signal transmitted by the first conductor 632 to the outside of the current-carrying wire 600 is often transmitted to the PCB. When the first conductor 632 is a tin wire, the first conductor 632 can be directly fixed to a solder pin of the PCB by soldering. Such a design can simplify the operation of electrically connecting the current-carrying wire 600 to the PCB, thereby improving the production efficiency.

In addition, the first conductor 632 may be helically wound to wrap the first insulation layer 620. For example, in the embodiment shown in FIG. 1, the first shield layer 631 is wrapped around the first insulation layer 620 first, and the first conductor 632 is then wound on the outer side of the first shield layer 631. For another example, in the embodiment shown in FIG. 4, the first conductor 632 is wound around the outer side of the first insulation layer 620 first, and the first shield layer 631 is then wrapped around the outer side of the first conductor 632. Alternatively, the first conductor 632 may be arranged at the outer side of the first insulation layer 620 in a direction parallel to the axial direction of the first current-carrying conductor 610. For example, in the embodiment shown in FIG. 1, the first conductor 632 is arranged in parallel between the first shield layer 631 and the second insulation layer 640. For another example, in the embodiment shown in FIG. 4, the first conductor 632 is arranged in parallel between the first insulation layer 620 and the first shield layer 631.

It shall be understood that the first metal conductor 650 may be an additionally provided conductor or wire, and after the first opening 641 is provided on the second insulation layer 640 of the current-carrying wire 600, the additionally provided conductor or wire is connected to the first shielding conductor structure 630 at the first opening 641. The additionally provided conductor or wire may be connected to the first shielding conductor structure 630 by soldering, or the additionally provided conductor or wire may be directly twisted together with the conductor of the first shield layer 631 or at least one strand of conductor of the first conductor 632.

In the current-carrying wire 600 according to some embodiments of the present disclosure, the first shield layer 631 includes a shield layer made of a single-sided-conductive flexible material and a shield layer which is a mesh woven from a plurality of strands of conductors.

In this embodiment, the first shield layer 631 includes both a single-sided-conductive flexible material and a shield layer which is a mesh woven from a plurality of strands of conductors, which can improve the reliability of the first shield layer 631, enabling the first shield layer 631 to more reliably detect a leakage current of the first current-carrying conductor 610, and to be less likely to crack or break.

Further, in the embodiments shown in FIG. 1 to FIG. 4, the second insulation layer 640 may be made of a flexible insulation film material, and winds around the first shielding conductor structure 630 or wraps on the first shielding conductor structure 630 in a direction parallel to an axial direction of the first current-carrying conductor 610; or the second insulation layer 640 may be an injection-molded insulation cover wrapping the outer side of the first shielding conductor structure 630. It shall be understood that in some other embodiments, the second insulation layer 640 may include a flexible insulation film material wound around the outer side of the first shielding conductor structure 630 or wrapping the first shielding conductor structure 630 in a direction parallel to an axial direction of the first current-carrying conductor 610, and an injection-molded insulation cover wrapping the outer side of the flexible insulation film material. Such a configuration can further improve the protective effect of the second insulation layer 640 on the first current-carrying conductor 610 and the first shielding conductor structure 630 in the current-carrying wire 600.

In addition, in accordance with the first aspect of the present disclosure, another embodiment provides a current-carrying wire 600, which includes a first current-carrying conductor 610, a first insulation layer 620, a first shielding conductor structure 630, a second insulation layer 640, and a first metal conductor 650.

The first insulation layer 620 wraps the first current-carrying conductor 610.

The first shielding conductor structure 630 is configured to detect a leakage current from the first current-carrying conductor 610. The first shielding conductor structure 630 includes a first shield layer 631 wrapping the first insulation layer 620. The first shielding conductor structure 630 has a first terminal adjacent to an input end of the first current-carrying conductor 610, a second terminal adjacent to an output end of the first current-carrying conductor 610, and a third terminal disposed between the first terminal and the second terminal.

The second insulation layer 640 wraps an outer side of the first shielding conductor structure 630.

The first metal conductor 650 is led out from the third terminal. The second insulation layer 640 has a first opening 641 configured for the first metal conductor 650 to pass through.

It shall be understood that the current-carrying wire provided in this embodiment is the same as those in the above embodiments, except that the first shielding conductor structure 630 in this embodiment does not include the first conductor 632. In other words, a schematic diagram of the current-carrying wire of this embodiment can be obtained by removing the first conductor 632 in FIG. 1 and FIG. 2.

In the current-carrying wire of the embodiment of the present disclosure, the first current-carrying conductor 610 is configured to supply an operating current to a load device. The first insulation layer 620 wraps the first current-carrying conductor 610 to avoid leakage. The first shielding conductor structure 630 arranged at the outer side of the first insulation layer 620 can effectively detect a possible leakage situation and transmit a signal to the outside of the current-carrying wire 600 to cut off the power supply when the first insulation layer 620 is damaged, thereby preventing accidental electric shocks to personnel and improving safety. Because the first opening 641 is provided on the second insulation layer 640, the first metal conductor 650 can be led out from the third terminal of the first shielding conductor structure 630. The first metal conductor 650 may pass through the first opening 641, such that the first shielding conductor structure 630 can transmit an electrical signal from the first terminal adjacent to the input end of the first current-carrying conductor 610 to the outside, transmit an electrical signal from the second terminal adjacent to the output end of the first current-carrying conductor 610 to the outside, or transmit an electrical signal from the third terminal to the outside through the first metal conductor 650, i.e., can transmit electrical signals to the outside from different positions at the same time. As such, segmented detection of the first shielding conductor structure 630 is realized, and more detection choices are provided, so that more comprehensive and reliable safety detection of the current-carrying wire can be achieved, thereby improving the power supply safety of the current-carrying wire.

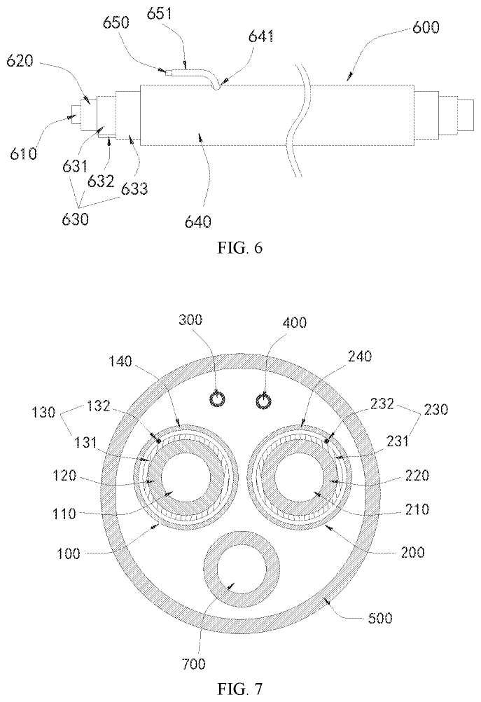

Referring to FIG. 5 and FIG. 6, in accordance with the first aspect of the present disclosure, another embodiment provides a current-carrying wire 600, which includes a first current-carrying conductor 610, a first insulation layer 620, a first shielding conductor structure 630, and a second insulation layer 640.

The first insulation layer 620 wraps the first current-carrying conductor 610.

The first shielding conductor structure 630 is configured to detect a leakage current from the first current-carrying conductor 610. The first shielding conductor structure 630 includes a first shield layer 631 wrapping the first insulation layer 620, a second shield layer 633 wrapping the first shield layer 631, and a first conductor 632 located between the first shield layer 631 and the second shield layer 633. The first conductor 632 is configured to transmit an electrical signal from the first shielding conductor structure 630 to outside of the current-carrying wire 600.

The second insulation layer 640 wraps an outer side of the first shielding conductor structure 630.

It shall be understood that a main difference between the embodiment shown in FIG. 5 and FIG. 6 and the embodiments shown in FIG. 1 to FIG. 4 lies in that the first shielding conductor structure 630 further includes the second shield layer 633 in addition to the first shield layer 631 and the first conductor 632, so that the first shielding conductor structure 630 can more reliably detect a leakage current of the first current-carrying conductor 610, and is less likely to crack or break.

In the current-carrying wire 600 of the embodiment of the present disclosure, the first current-carrying conductor 610 is configured to supply an operating current to a load device. The first insulation layer 620 wraps the first current-carrying conductor 610 to avoid leakage. The first shielding conductor structure 630 arranged at the outer side of the first insulation layer 620 can effectively detect a possible leakage situation and transmit a signal to the outside of the current-carrying wire 600 to cut off the power supply when the first insulation layer 620 is damaged, thereby preventing accidental electric shocks to personnel and improving safety. The first shielding conductor structure 630 is composed of three parts: the first shield layer 631, the first conductor 632, and the second shield layer 633. The first shield layer 631 and the second shield layer 633 both wrap the first current-carrying conductor to comprehensively detect a leakage current on the entire first current-carrying conductor 610. The use of the structure including a plurality of shield layers can improve the reliability of leakage detection. The first conductor 632 can conveniently and reliably transmit an electrical signal from the first shielding conductor structure 630 to outside of the current-carrying wire 600. In addition, the second insulation layer 640 is further used to wrap the first shielding conductor structure 630, to achieve a closer contact between the first conductor 632 and the first shield layer 631 and the second shield layer 633, so that the electrical signals on the first shield layer 631 and the second shield layer 633 can be more reliably transmitted to the first conductor 632. Therefore, the first shielding conductor structure 630, composed of the first shield layer 631, the first conductor 632 and the second shield layer 633, has the advantages of comprehensive and reliable detection and convenient and reliable electrical signal transmission, thereby improving the power supply safety of the current-carrying wire 600.

Referring to FIG. 6, in the current-carrying wire 600 according to some embodiments of the present disclosure, the first shielding conductor structure 630 has a first terminal adjacent to an input end of the first current-carrying conductor 610, a second terminal adjacent to an output end of the first current-carrying conductor 610, and a third terminal disposed between the first terminal and the second terminal, the current-carrying wire 600 further includes a first metal conductor 650 led out from the third terminal, and the second insulation layer 640 has a first opening 641 configured for the first metal conductor 650 to pass through.

It shall be understood that taking a placement direction of the current-carrying wire 600 shown in FIG. 6 as an example, if the left end of the current-carrying wire 600 is used for connecting to a plug for supplying power and the right end of the current-carrying wire 600 is used for connecting to a load device, the first terminal of the first shielding conductor structure 630 is located on the left side shown in FIG. 6, the second terminal of the first shielding conductor structure 630 is located on the right side shown in FIG. 6, and the third terminal is located between the first terminal and the second terminal, for example, on an inner side of the first opening 641 shown in FIG. 6.

In this embodiment, the first metal conductor 650 led out from the third terminal can transmit an electrical signal on the first shielding conductor structure 630 from the third terminal to outside of the current-carrying wire 600, so that the first shielding conductor structure 630 can transmit an electrical signal from the first terminal on the left side to the outside of the current-carrying wire 600, transmit an electrical signal from the second terminal on the right side to the outside of the current-carrying wire 600, or transmit an electrical signal from the third terminal in the middle to the outside of the current-carrying wire 600. As such, leakage detection of the current-carrying wire 600 can be realized at different positions. Furthermore, the first shielding conductor structure 630 may be divided into two segments, the first segment being located between the first terminal on the left side and the third terminal in the middle, and the second segment being located between the third terminal in the middle and the second terminal on the right side, so that a disconnection detection can be performed for the two segments respectively, thereby meeting various requirements for safety detection of the current-carrying wire 600.

In addition, the second insulation layer 640 has the first opening 641 for the first metal conductor 650 to pass through, i.e., the second insulation layer 640 is broken at the first opening 641, and the integrity of the second insulation layer 640 is guaranteed as much as possible at other positions, so as to prevent a reduction in the protective effect of the second insulation layer 640 on the first current-carrying conductor 610 and the first shielding conductor structure 630.

Referring to FIG. 6, in the current-carrying wire 600 according to some embodiments of the present disclosure, in the current-carrying wire 600 according to some embodiments of the present disclosure, an insulation cover 651 is arranged at outside of the first metal conductor 650.

In this embodiment, the insulation cover 651 is additionally provided to protect the first metal conductor 650, which not only can prevent an electrical signal transmitted on the first metal conductor 650 from other interference, but also can prevent the first metal conductor 650 from being easily broken by an external force.

In the current-carrying wire 600 according to some embodiments of the present disclosure, the first shield layer 631 is made of a single-sided-conductive flexible material, the first shield layer 631 has an insulation surface facing inward and in contact with a surface of the outer side of the first insulation layer 620, and a conductive surface facing outward and in contact with the first conductor 632 and the second shield layer 633; and the second shield layer 633 is a mesh woven from a plurality of strands of conductors to wrap the first shield layer 631.

The single-sided-conductive flexible material has two surfaces: an insulation surface and a conductive surface. Therefore, arranging the insulation surface of the first shield layer 631 to face inward and the conductive surface of the first shield layer 631 to face outward can ensure a reliable electrical connection relationship between the first shield layer 631 and the first conductor 632 and the second shield layer 633.

In the current-carrying wire 600 according to some embodiments of the present disclosure, the first shield layer 631 is a mesh woven from a plurality of strands of conductors to wrap the first insulation layer 620; and the second shield layer 633 is made of a single-sided-conductive flexible material, and the second shield layer 633 has a conductive surface facing inward and in contact with the first conductor 632 and the first shield layer 631, and the insulation surface facing outward and in contact with a surface of an inner side of the second insulation layer 640.

Similarly, the single-sided-conductive flexible material has two surfaces: an insulation surface and a conductive surface, arranging the insulation surface of the second shield layer 633 to face outward and the conductive surface of the second shield layer 633 to face inward can ensure a reliable electrical connection relationship between the second shield layer 633 and the first conductor 632 and the second shield layer 631.

In the current-carrying wire 600 according to some embodiments of the present disclosure, the first conductor 632 is a single-strand wire or a multi-strand wire; and the first conductor 632 is helically wound to wrap the outer side of the first insulation layer 620, or is arranged at the outer side of the first insulation layer 620 in a direction parallel to an axial direction of the first current-carrying conductor 610.

It shall be understood that in an embodiment, the first conductor 632 is a tin wire. Because the current-carrying wire 600 is generally connected to a PCB, an electrical signal transmitted by the first conductor 632 to the outside of the current-carrying wire 600 is often transmitted to the PCB. When the first conductor 632 is a tin wire, the first conductor 632 can be directly fixed to a solder pin of the PCB by soldering. Such a design can simplify the operation of electrically connecting the current-carrying wire 600 to the PCB, thereby improving the production efficiency.

For example, in the embodiment shown in FIG. 5, the first conductor 632 is helically wound to wrap the outer side of the first shield layer 631, and the second shield layer 633 is then wrapped around the outer side of the first conductor 632; or the first conductor 632 is arranged in parallel between the first shield layer 631 and the second shield layer 633.

In the current-carrying wire 600 according to some embodiments of the present disclosure, the second insulation layer 640 may be made of a flexible insulation film material, and winds around the first shielding conductor structure 630 or wraps on the first shielding conductor structure 630 in a direction parallel to an axial direction of the first current-carrying conductor 610; or the second insulation layer 640 may be an injection-molded insulation cover.

It shall be understood that in some other embodiments, the second insulation layer 640 may include a flexible insulation film material wound around the outer side of the first shielding conductor structure 630 or wrapping the first shielding conductor structure 630 in a direction parallel to an axial direction of the first current-carrying conductor 610, and an injection-molded insulation cover wrapping the outer side of the flexible insulation film material. Such a configuration can further improve the protective effect of the second insulation layer 640 on the first current-carrying conductor 610 and the first shielding conductor structure 630 in the current-carrying wire 600.

The above is a description of the embodiments of the current-carrying wire in accordance with the first aspect of the present disclosure. Embodiments of a power cord in accordance with a second aspect of the present disclosure will be further described below with reference to the accompanying drawings.

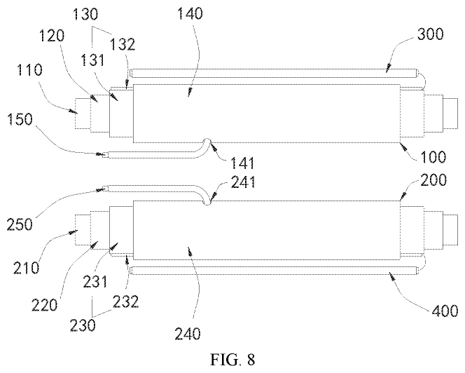

Referring to FIG. 7 and FIG. 8, in accordance with the second aspect of the present disclosure, an embodiment provides a power cord, which includes a first current-carrying wire 100, a second current-carrying wire 200, and a fifth insulation layer 500.

The first current-carrying wire 100 includes a first current-carrying conductor 110, a first insulation layer 120 wrapping the first current-carrying conductor 110, and a first shielding conductor structure 130. The first shielding conductor structure 130 is configured to detect a leakage current from the first current-carrying conductor 110. The first shielding conductor structure 130 includes a first shield layer 131 wrapping the first insulation layer 120 and a first conductor 132 in direct contact with the first shield layer 131. The first conductor 132 is configured to transmit an electrical signal from the first shielding conductor structure 130 to outside of the current-carrying wire.

The second current-carrying wire 200 includes a second current-carrying conductor 210, a third insulation layer 220 wrapping the second current-carrying conductor 210, and a second shielding conductor structure 230. The second shielding conductor structure 230 is configured to detect a leakage current from the second current-carrying conductor 210. The second shielding conductor structure 230 includes a third shield layer 231 wrapping the third insulation layer 220 and a second conductor 232 in direct contact with the third shield layer 231. The second conductor 232 is configured to transmit an electrical signal from the second shielding conductor structure 230 to outside of the current-carrying wire.

The fifth insulation layer 500 encloses the first current-carrying wire 100 and the second current-carrying wire 200.

The first shielding conductor structure 130 and the second shielding conductor structure 230 are separated from each other in the fifth insulation layer 500, so that the first shielding conductor structure 130 is insulated from the second shielding conductor structure 230.

According to the power cord of the embodiment of the present disclosure, in the first current-carrying wire 100 and the second current-carrying wire 200 of the power cord, the first current-carrying conductor 110 and the second current-carrying conductor 210 are each configured to supply an operating current to a load device. The first insulation layer 120 wraps the first current-carrying conductor 110 and the third insulation layer 220 wraps the second current-carrying conductor 210 to avoid leakage. The first shielding conductor structure 130 arranged at the outer side of the first insulation layer 120 can effectively detect a possible leakage situation and transmit a signal to the outside of the first current-carrying wire 100 to cut off the power supply when the first insulation layer 120 is damaged, and the second shielding conductor structure 230 arranged at the outer side of the third insulation layer 220 can effectively detect a possible leakage situation and transmit a signal to the outside of the second current-carrying wire 200 to cut off the power supply when the third insulation layer 220 is damaged, thereby preventing accidental electric shocks to personnel and improving safety. The first shielding conductor structure 130 includes the first shield layer 131 and the first conductor 132. The second shielding conductor structure 230 includes the third shield layer 231 and the second conductor 232. The first shield layer 131 wraps the first current-carrying conductor 110 to comprehensively detect a leakage current on the entire first current-carrying conductor 110. The third shield layer 231 wraps the second current-carrying conductor 210 to comprehensively detect a leakage current on the entire second current-carrying conductor 210. The first conductor 132 in direct contact with the first shield layer 131 can conveniently and reliably transmit an electrical signal from the first shielding conductor structure 130 to outside of the first current-carrying wire 100. The second conductor 232 in direct contact with the third shield layer 231 can conveniently and reliably transmit an electrical signal from the second shielding conductor structure 230 to outside of the second current-carrying wire 200. Therefore, the first shielding conductor structure 130 composed of the first shield layer 131 and the first conductor 132 and the second shielding conductor structure 230 composed of the third shield layer 231 and the second conductor 232 have the advantages of comprehensive detection and convenient and reliable electrical signal transmission, thereby improving the power supply safety of the first current-carrying wire 100 and the second current-carrying wire 200, and further improving the power supply safety of the power cord.

Referring to FIG. 7 and FIG. 8, in the power cord according to some embodiments of the present disclosure, the first current-carrying wire 100 further includes a second insulation layer 140 wrapping the first shielding conductor structure 130, and the second current-carrying wire 200 further includes a fourth insulation layer 240 wrapping the second shielding conductor structure 230.

It shall be understood that with the use of the second insulation layer 140 to wrap the first shielding conductor structure 130 and the use of the fourth insulation layer 240 to wrap the second shielding conductor structure 230, the first shielding conductor structure 130 can be insulated from the second shielding conductor structure 230, thereby preventing leakage detection of the first current-carrying wire 100 and leakage detection of the second current-carrying wire 200 from interfering with each other.

In the embodiment shown in FIG. 7 and FIG. 8, both the second insulation layer 140 and the fourth insulation layer 240 are present. In some other extended embodiments, neither of the second insulation layer 140 and the fourth insulation layer 240 is provided. Even when only one of the second insulation layer 140 and the fourth insulation layer 240 is provided, the first shielding conductor structure 130 can be insulated from the second shielding conductor structure 230, thereby preventing leakage detection of the first current-carrying wire 100 and leakage detection of the second current-carrying wire 200 from interfering with each other. Although subsequent embodiments are illustrated and described using an example where both the second insulation layer 140 and the fourth insulation layer 240 are present, these embodiments may be extended to encompass the cases where either of the second insulation layer 140 and the fourth insulation layer 240 is not provided.

In addition, in the power cord according to some embodiments of the present disclosure, space in the fifth insulation layer 500 not occupied by the first current-carrying wire 100 and the second current-carrying wire 200 is filled with an insulation material. It shall be understood that when the fifth insulation layer 500 is filled therein with the insulation material and the first shielding conductor structure 130 and the second shielding conductor structure 230 are separated from each other in the fifth insulation layer 500, the first shielding conductor structure 130 can be insulated from the second shielding conductor structure 230 even if none of the second insulation layer 140 and the fourth insulation layer 240 is provided.

Referring to FIG. 7, the power cord according to some embodiments of the present disclosure further includes a third current-carrying wire 700 arranged in the fifth insulation layer 500. The first current-carrying wire 100 may be used as a live wire, the second current-carrying wire 200 may be used as a neutral wire or as another live wire, and the third current-carrying wire 700 may be used as a ground wire. The third current-carrying wire 700 may be provided with an insulation cover.

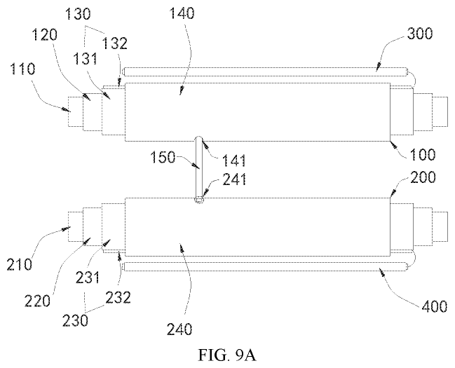

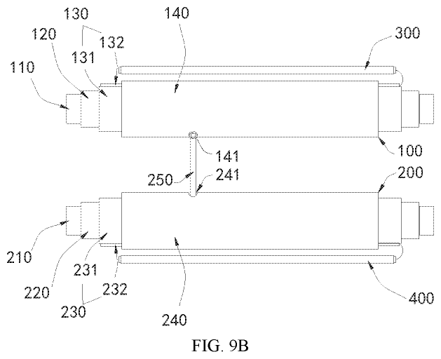

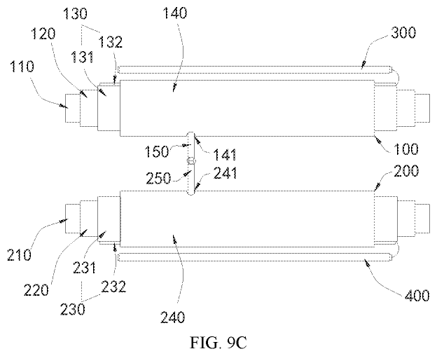

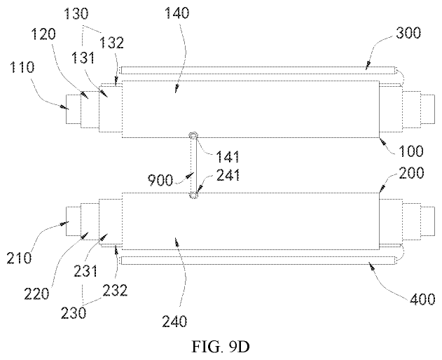

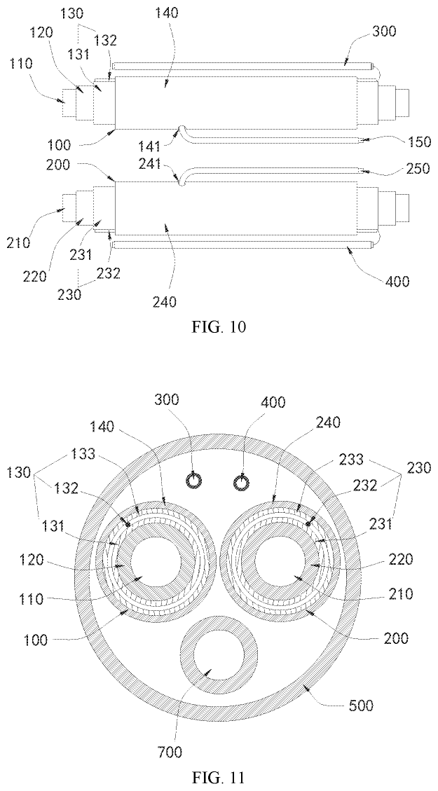

In the power cord according to some embodiments of the present disclosure, the first shielding conductor structure 130 has a first terminal adjacent to an input end of the power cord, a second terminal adjacent to an output end of the power cord, and a third terminal disposed between the first terminal and the second terminal; the second shielding conductor structure 230 includes a fourth terminal adjacent to the input end, a fifth terminal adjacent to the output end, and a sixth terminal disposed between the fourth terminal and the fifth terminal; and
the first current-carrying wire 100 and the second current-carrying wire 200 further satisfy any one of the following four cases:
case one: the first current-carrying wire 100 further includes a first metal conductor 150 led out from the third terminal, and the first metal conductor 150 is connected to the sixth terminal, for example, as shown in FIG. 9A.
case two: the second current-carrying wire 200 further includes a second metal conductor 250 led out from the sixth terminal, and the second metal conductor 250 is connected to the third terminal, for example, as shown in FIG. 9B.
case three: the first current-carrying wire 100 further includes a first metal conductor 150 led out from the third terminal, the second current-carrying wire 200 further includes a second metal conductor 250 led out from the sixth terminal, and the first metal conductor 150 is connected to the second metal conductor 250, for example, as shown in FIG. 9C.
case four: The power cord further includes a third metal conductor 900, and two terminals of the third metal conductor 900 are respectively connected to the third terminal and the sixth terminal, for example, as shown in FIG. 9D.

In the power cord according to some embodiments of the present disclosure, in the presence of the second insulation layer 140, the second insulation layer 140 has a first opening 141 configured for the first metal conductor 150 to pass through; and in the presence of the fourth insulation layer 240, the fourth insulation layer 240 is provided with a second opening 241 configured for the second metal conductor 250 to pass through.

It shall be understood that taking a placement direction of the power cord shown in FIG. 8 as an example, if the left end of the power cord is used for connecting to a plug for supplying power and the right end of the power cord is used for connecting to a load device, the first terminal of the first shielding conductor structure 130 is located on the left side shown in FIG. 8, the second terminal of the first shielding conductor structure 130 is located on the right side shown in FIG. 8, and the third terminal is located between the first terminal and the second terminal, for example, on an inner side of the first opening 141 shown in FIG. 8. The first metal conductor 150 led out from the third terminal can transmit an electrical signal on the first shielding conductor structure 130 from the third terminal to outside of the first current-carrying wire 100, so that the first shielding conductor structure 130 can transmit an electrical signal from the first terminal on the left side to the outside of the first current-carrying wire 100, transmit an electrical signal from the second terminal on the right side to the outside of the first current-carrying wire 100, or transmit an electrical signal from the third terminal in the middle to the outside of the first current-carrying wire 100. As such, leakage detection of the first current-carrying wire 100 can be realized at different positions. Furthermore, the first shielding conductor structure 130 may be divided into two segments, the first segment being located between the first terminal on the left side and the third terminal in the middle, and the second segment being located between the third terminal in the middle and the second terminal on the right side, so that a disconnection detection can be performed for the two segments respectively, thereby meeting various requirements for safety detection. In addition, the second insulation layer 140 has the first opening 141 for the first metal conductor 150 to pass through, i.e., the second insulation layer 140 is broken at the first opening 141, and the integrity of the second insulation layer 140 is guaranteed as much as possible at other positions, so as to prevent a reduction in the protective effect of the second insulation layer 140 on the first current-carrying conductor 110 and the first shielding conductor structure 130.

Similarly, the fourth terminal of the second shielding conductor structure 230 is located on the left side shown in FIG. 8, the fifth terminal of the second shielding conductor structure 230 is located on the right side shown in FIG. 8, and the sixth terminal is located between the fourth terminal and the fifth terminal, for example, on an inner side of the second opening 241 shown in FIG. 8. The second metal conductor 250 led out from the sixth terminal can transmit an electrical signal on the second shielding conductor structure 230 from the sixth terminal to outside of the second current-carrying wire 200, so that the second shielding conductor structure 230 can transmit an electrical signal from the fourth terminal on the left side to the outside of the second current-carrying wire 200, transmit an electrical signal from the fifth terminal on the right side to the outside of the second current-carrying wire 200, or transmit an electrical signal from the sixth terminal in the middle to the outside of the second current-carrying wire 200. As such, leakage detection of the second current-carrying wire 200 can be realized at different positions. Furthermore, the second shielding conductor structure 230 may be divided into two segments, the first segment being located between the fourth terminal on the left side and the sixth terminal in the middle, and the second segment being located between the sixth terminal in the middle and the fifth terminal on the right side, so that a disconnection detection can be performed for the two segments respectively, thereby meeting various requirements for safety detection. In addition, the fourth insulation layer 240 is provided with the second opening 241 for the second metal conductor 250 to pass through, i.e., the fourth insulation layer 240 is broken at the second opening 241, and the integrity of the fourth insulation layer 240 is guaranteed as much as possible at other positions, so as to prevent a reduction in the protective effect of the fourth insulation layer 240 on the second current-carrying conductor 210 and the second shielding conductor structure 230.

It should also be noted that taking FIG. 9C as an example, because the first metal conductor 150 is connected to the second metal conductor 250, i.e., the third terminal of the first shielding conductor structure 130 and the sixth terminal of the second shielding conductor structure 230 are electrically connected together, an association point is formed between the shielding conductor structures of the first current-carrying wire 100 and the second current-carrying wire 200, and the two shielding conductor structures are no longer independent of each other. For example, the first segment of the first shielding conductor structure 130 between the first terminal on the left side and the third terminal in the middle is electrically connected to the two segments of the second shielding conductor structure 230 by the first metal conductor 150 and the second metal conductor 250. Similarly, the second segment of the first shielding conductor structure 130 between the third terminal in the middle and the second terminal on the right side is electrically connected to the two segments of the second shielding conductor structure 230 by the first metal conductor 150 and the second metal conductor 250. As such, the first shielding conductor structure 130 and the second shielding conductor structure 230 form a shield network having a plurality of detection segments and capable of constructing a plurality of different detection choices, thereby greatly improving the feasibility and flexibility of leakage detection of the power cord and open-circuit detection of the shield structures, and improving the power supply safety.

Referring to FIG. 8, in the power cord according to some embodiments of the present disclosure, an insulation cover is respectively arranged at outside of the first metal conductor 150 and outside of the second metal conductor 250.

In this embodiment, the insulation cover is additionally provided on outside of the first metal conductor 150 and the outer side of the second metal conductor 250 to protect the first metal conductor 150 and the second metal conductor 250, which not only can prevent an electrical signal transmitted on the first metal conductor 150 and the second metal conductor 250 from other interference, but also can prevent the first metal conductor 150 and the second metal conductor 250 from being easily broken by an external force.

In the power cord according to some embodiments of the present disclosure, for example, in the case one, the first metal conductor 150 extends directly from the second opening 241 to the sixth terminal of the second shielding conductor structure 230, and is electrically connected to the sixth terminal by soldering, for example, as shown in FIG. 9A; in the case two, the second metal conductor extends directly from the first opening 141 to the third terminal of the first shielding conductor structure 130, and is electrically connected to the third terminal by soldering, for example, as shown in FIG. 9B; in the case three, the first metal conductor 150 and the second metal conductor are electrically connected between the third terminal and the sixth terminal by soldering, for example, as shown in FIG. 9C; and in the case four, one end of the third metal conductor 900 extends from the first opening 141 to the third terminal of the first shielding conductor structure 130 and is electrically connected to the third terminal by soldering, and the other end of the third metal conductor 900 extends from the second opening 241 to the sixth terminal of the second shielding conductor structure 230 and is electrically connected to the sixth terminal by soldering, for example, as shown in FIG. 9D.

It shall be understood that soldering positions on the first metal conductor 150 and the second metal conductor 250 can be selected according to the convenience at the time of soldering.

In the power cord according to some embodiments of the present disclosure, the first metal conductor 150 and the second metal conductor 250 extend to a position adjacent to the input end of the power cord, for example, as shown in FIG. 8; or the first metal conductor 150 and the second metal conductor 250 extend to a position adjacent to the output end of the power cord for electrical connection, for example, as shown in FIG. 10.

It shall be understood that when the first metal conductor 150 and the second metal conductor 250 extend to a position adjacent to the input end of the power cord or a position adjacent to the output end of the power cord for electrical connection, the first metal conductor 150 and the second metal conductor 250 may be directly soldered together to realize electrical connection, may be short-circuited together by a terminal bar, or may be connected to a PCB and electrically connected by the PCB.

Referring to FIG. 8, in the power cord according to some embodiments of the present disclosure, the first conductor 132 and the second conductor 232 are each a multi-strand wire, the first metal conductor 150 is formed by at least one strand in the first conductor 132 led out from the third terminal, and the second metal conductor 250 is formed by at least one strand in the second conductor 232 led out from the sixth terminal.

In this embodiment, the first conductor 132 is a multi-strand wire, from which at least one strand is led out from the third terminal to serve as the first metal conductor 150. Therefore, the first conductor 132 in the first shielding conductor structure 130 can transmit an electrical signal from the first terminal to the outside of the first current-carrying wire 100, transmit an electrical signal from the second terminal to the outside of the first current-carrying wire 100, or transmit an electrical signal from the third terminal to the outside of the first current-carrying wire 100. Similarly, the second conductor 232 is a multi-strand wire, from which at least one strand is led out from the sixth terminal to serve as the second metal conductor 250. Therefore, the second conductor 232 in the second shielding conductor structure 230 can transmit an electrical signal from the fourth terminal to the outside of the second current-carrying wire 200, transmit an electrical signal from the fifth terminal to the outside of the second current-carrying wire 200, or transmit an electrical signal from the sixth terminal to the outside of the second current-carrying wire 200. It shall be understood that the first metal conductor 150 and the second metal conductor 250 obtained in this manner have the advantages of convenient operation and reliable signal transmission.

It shall be understood that in an embodiment, the first conductor 132 and the second conductor 232 are tin wires. Because the power cord is generally connected to a PCB, an electrical signal transmitted by the first conductor 132 to the outside of the first current-carrying wire 100 and an electrical signal transmitted by the second conductor 232 to the outside of the second current-carrying wire 200 are often transmitted to the PCB. When the first conductor 132 and the second conductor 232 are tin wires, the first conductor 132 and the second conductor 232 can be directly fixed to a solder pin of the PCB by soldering. Such a design can simplify the operation of electrically connecting the power cord to the PCB, thereby improving the production efficiency.

In the power cord according to some embodiments of the present disclosure, the first shield layer 131 is a mesh woven from a plurality of strands of conductors to wrap the first insulation layer 120, the third shield layer 231 is a mesh woven from a plurality of strands of conductors to wrap the third insulation layer 220, the first metal conductor 150 is formed by at least one strand of conductor in the first shield layer 131 led out from the third terminal, and the second metal conductor 250 is formed by at least one strand of conductor in the third shield layer 231 led out from the sixth terminal.

It shall be understood that different from the above embodiments where at least one strand in the first conductor 132 is led out from the third terminal to serve as the first metal conductor 150 and at least one strand in the second conductor 232 is led out from the sixth terminal to serve as the second metal conductor 250, in this embodiment, at least one strand of conductor in the first shield layer 131 is led out from the third terminal to serve as the first metal conductor 150, and at least one strand of conductor in the third shield layer 231 is led out from the sixth terminal to serve as the second metal conductor 250, which can achieve the same effect and has the advantages of convenient operation and reliable signal transmission.

In the power cord according to some embodiments of the present disclosure, the first shield layer 131 is made of a single-sided-conductive flexible material; the first shield layer 131 is helically wound to wrap the first insulation layer 120, or wraps the first insulation layer 120 in a direction parallel to an axial direction of the first current-carrying conductor 110; the third shield layer 231 is made of a single-sided-conductive flexible material; and the third shield layer 231 is helically wound to wrap the third insulation layer 220, or wraps the third insulation layer 220 in a direction parallel to an axial direction of the second current-carrying conductor 210.

The single-sided-conductive flexible material has two surfaces: an insulation surface and a conductive surface. Therefore, in order to ensure a reliable electrical connection relationship between the first shield layer 131 and the first conductor 132, the conductive surface of the first shield layer 131 needs to be arranged facing the first conductor 132. For example, in the embodiment shown in FIG. 7 where the first conductor 132 is located between the first shield layer 131 and the second insulation layer 140, the insulation surface of the first shield layer 131 faces inward and wraps the first insulation layer 120, and the conductive surface of the first shield layer 131 faces outward and is contact with the first conductor 132. It shall be understood that in the embodiment where the first conductor 132 is located between the first insulation layer 120 and the first shield layer 131, the conductive surface of the first shield layer 131 faces inward and wraps both the first insulation layer 120 and the first conductor 132, so that the conductive surface of the first shield layer 131 is in reliable contact with the first conductor 132.

Similarly, in order to ensure a reliable electrical connection relationship between the third shield layer 231 and the second conductor 232, the conductive surface of the third shield layer 231 needs to be arranged facing the second conductor 232. For example, in the embodiment shown in FIG. 7 where the second conductor 232 is located between the third shield layer 231 and the fourth insulation layer 240, the insulation surface of the third shield layer 231 faces inward and wraps the third insulation layer 220, and the conductive surface of the third shield layer 231 faces outward and is contact with the second conductor 232. It shall be understood that in the embodiment where the second conductor 232 is located between the third insulation layer 220 and the third shield layer 231, the conductive surface of the third shield layer 231 faces inward and wraps both the third insulation layer 220 and the second conductor 232, so that the conductive surface of the third shield layer 231 is in reliable contact with the second conductor 232.

In the power cord according to some embodiments of the present disclosure, the first shield layer 131 is a mesh woven from a plurality of strands of conductors to wrap the first insulation layer 120; and the third shield layer 231 is a mesh woven from a plurality of strands of conductors to wrap the third insulation layer 220.

Compared with the above embodiments in which a single-sided-conductive flexible material is used as the first shield layer 131, a first shield layer 131 and a third shield layer 231 in this embodiment are made of a different material, i.e., uses a mesh woven from a plurality of strands of conductors as each of the first shield layer 131 and the third shield layer 231. In this way, at least one strand of conductor may be pulled out from the first shield layer 131 and passes through the first opening 141 to serve as the first metal conductor 150, and at least one strand of conductor may be pulled out from the third shield layer 231 and passes through the second opening 241 to serve as the second metal conductor 250.

In the power cord according to some embodiments of the present disclosure, the first shield layer 131 includes a shield layer made of a single-sided-conductive flexible material and a shield layer which is a mesh woven from a plurality of strands of conductors; and the third shield layer 231 includes a shield layer made of a single-sided-conductive flexible material and a shield layer which is a mesh woven from a plurality of strands of conductors.

In this embodiment, the first shield layer 131 includes both a single-sided-conductive flexible material and a shield layer which is a mesh woven from a plurality of strands of conductors, which can improve the reliability of the first shield layer 131, enabling the first shield layer 131 to more reliably detect a leakage current of the first current-carrying conductor 110, and to be less likely to crack or break. Similarly, the third shield layer 231 includes both a single-sided-conductive flexible material and a shield layer which is a mesh woven from a plurality of strands of conductors, which can improve the reliability of the third shield layer 231, enabling the third shield layer 231 to more reliably detect a leakage current of the second current-carrying conductor 210, and to be less likely to crack or break.

In the power cord according to some embodiments of the present disclosure, the first conductor 132 is located between the first insulation layer 120 and the first shield layer 131, for example, as shown in FIG. 7; or the first conductor 132 is located between the first shield layer 131 and the second insulation layer 140 when the second insulation layer 140 is present; and the second conductor 232 is located between the third insulation layer 220 and the third shield layer 231, for example, as shown in FIG. 7; or the second conductor 232 is located between the third shield layer 231 and the fourth insulation layer 240 when the fourth insulation layer 240 is present.

It shall be understood that in this embodiment, the relative positions of the first shield layer 131 and the first conductor 132 that constitute the first shielding conductor structure 130 can be interchanged, as long as it can be ensured that the first shield layer 131 and the first conductor 132 are in direct contact with each other and have a reliable electrical connection relationship to ensure the stability of electrical signal transmission. Similarly, the relative positions of the third shield layer 231 and the second conductor 232 that constitute the second shielding conductor structure 230 can be interchanged, as long as it can be ensured that the third shield layer 231 and the second conductor 232 are in direct contact with each other and have a reliable electrical connection relationship to ensure the stability of electrical signal transmission.

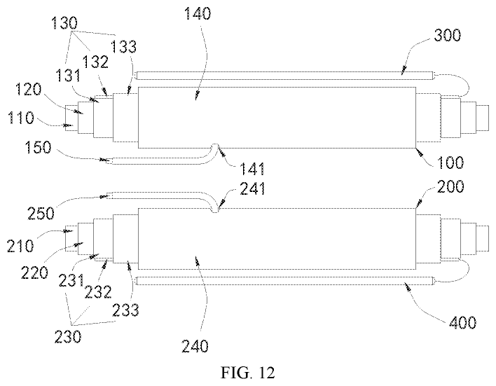

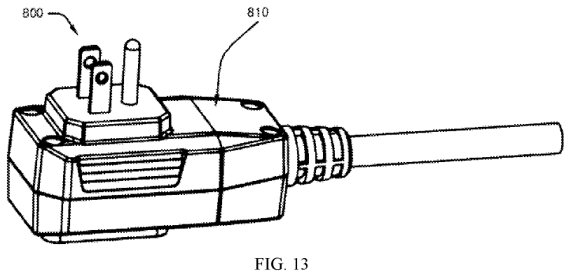

Referring to FIG. 11 and FIG. 12, in the power cord according to some embodiments of the present disclosure, the first shielding conductor structure 130 further includes a second shield layer 133 wrapping the first shield layer 131 and the first conductor 132, and the first conductor 132 is located between the first shield layer 131 and the second shield layer 133; and the second shielding conductor structure 230 further includes a fourth shield layer 233 wrapping the third shield layer 231 and the second conductor 232, and the second conductor 232 is located between the third shield layer 231 and the fourth shield layer 233.

It shall be understood that a main difference between the embodiment shown in FIG. 11 and FIG. 12 and the embodiment shown in FIG. 7 and FIG. 8 lies in that the first shielding conductor structure 130 further includes the second shield layer 133 in addition to the first shield layer 131 and the first conductor 132, and the second shielding conductor structure 230 further includes the fourth shield layer 233 in addition to the third shield layer 231 and the second conductor 232, so that the second shielding conductor structure 230 can more reliably detect a leakage current of the second current-carrying conductor 210, and is less likely to crack or break.

In the power cord according to some embodiments of the present disclosure, the first shield layer 131 is made of a single-sided-conductive flexible material, the first shield layer 131 has an insulation surface facing inward and in contact with a surface of the outer side of the first insulation layer 120, and a conductive surface facing outward and in contact with the first conductor 132 and the second shield layer 133; the second shield layer 133 is a mesh woven from a plurality of strands of conductors to wrap the first shield layer 131; the third shield layer 231 is made of a single-sided-conductive flexible material, the third shield layer 231 has an insulation surface facing inward and in contact with a surface of an outer side of the third insulation layer 220, and a conductive surface facing outward and in contact with the second conductor 232 and the fourth shield layer 233; and the fourth shield layer 233 is a mesh woven from a plurality of strands of conductors to wrap the third shield layer 231.

The single-sided-conductive flexible material has two surfaces: an insulation surface and a conductive surface. Therefore, arranging the insulation surface of the first shield layer 131 to face inward and the conductive surface of the first shield layer 131 to face outward can ensure a reliable electrical connection relationship between the first shield layer 131 and the first conductor 132 and the second shield layer 133. Similarly, arranging the insulation surface of the third shield layer 231 to face inward and the conductive surface of the third shield layer 231 to face outward can ensure a reliable electrical connection relationship between the third shield layer 231 and the second conductor 232 and the fourth shield layer 233.

In the power cord according to some embodiments of the present disclosure, the first shield layer 131 is a mesh woven from a plurality of strands of conductors to wrap the first insulation layer 120; the second shield layer 133 is made of a single-sided-conductive flexible material, and the second shield layer 133 has a conductive surface facing inward and in contact with the first conductor 132 and the first shield layer 131, and the insulation surface facing outward and in contact with a surface of an inner side of the second insulation layer 140; the third shield layer 231 is a mesh woven from a plurality of strands of conductors to wrap the third insulation layer 220; the fourth shield layer 233 is made of a single-sided-conductive flexible material, and the fourth shield layer 233 has a conductive surface facing inward and in contact with the second conductor 232 and the third shield layer 231; and in the presence of the fourth insulation layer 240, the fourth shield layer 233 has an insulation surface facing outward and in contact with a surface of an inner side of the fourth insulation layer 240.

Similarly, because two surfaces of the single-sided-conductive flexible material include an insulation surface and a conductive surface, arranging the insulation surface of the second shield layer 133 to face outward and the conductive surface of the second shield layer 133 to face inward can ensure a reliable electrical connection relationship between the second shield layer 133 and the first conductor 132 and the second shield layer 131. Arranging the insulation surface of the fourth shield layer 233 to face outward and the conductive surface of the fourth shield layer 233 to face inward can ensure a reliable electrical connection relationship between the fourth shield layer 233 and the second conductor 232 and the third shield layer 231.

In the power cord according to some embodiments of the present disclosure, the first conductor 132 is helically wound to wrap the outer side of the first insulation layer 120, or is arranged at the outer side of the first insulation layer 120 in a direction parallel to an axial direction of the first current-carrying conductor 110; and the second conductor 232 is helically wound to wrap an outer side of the third insulation layer 220, or is arranged at the outer side of the third insulation layer 220 in a direction parallel to an axial direction of the second current-carrying conductor 210.

For example, in the embodiment shown in FIG. 11, the first conductor 132 is helically wound to wrap the outer side of the first shield layer 131, and the second shield layer 133 is then wrapped around the outer side of the first conductor 132; or the first conductor 132 is arranged in parallel between the first shield layer 131 and the second shield layer 133; and the second conductor 232 is helically wound to wrap the outer side of the third shield layer 231, and the fourth shield layer 233 is then wrapped around the outer side of the second conductor 232; or the second conductor 232 is arranged in parallel between the third shield layer 231 and the fourth shield layer 233.

In the power cord according to some embodiments of the present disclosure, the second insulation layer 140 may be made of a flexible insulation film material, and winds around the first shielding conductor structure 130 or wraps on the first shielding conductor structure 130 in a direction parallel to an axial direction of the first current-carrying conductor 110; or the second insulation layer 140 may be an injection-molded insulation cover; or the fourth insulation layer 240 may be made of a flexible insulation film material, and winds around the second shielding conductor structure 230 or wraps on the second shielding conductor structure 230 in a direction parallel to an axial direction of the second current-carrying conductor 210; or the fourth insulation layer 240 may be an injection-molded insulation cover.

It shall be understood that the second insulation layer 140 may include a flexible insulation film material wound around the outer side of the first shielding conductor structure 130 or wrapping the first shielding conductor structure 130 in a direction parallel to an axial direction of the first current-carrying conductor 110, and an injection-molded insulation cover wrapping the outer side of the flexible insulation film material. Such a configuration can further improve the protective effect of the second insulation layer 140 on the first current-carrying conductor 110 and the first shielding conductor structure 130 in the first current-carrying wire 100. Similarly, in some other embodiments, the fourth insulation layer 240 may include a flexible insulation film material wound around the outer side of the second shielding conductor structure 230 or wrapping the second shielding conductor structure 230 in a direction parallel to an axial direction of the second current-carrying conductor 210, and an injection-molded insulation cover wrapping the outer side of the flexible insulation film material. Such a configuration can further improve the protective effect of the fourth insulation layer 240 on the second current-carrying conductor 210 and the second shielding conductor structure 230 in the second current-carrying wire 200.

Referring to FIG. 7 and FIG. 8, or FIG. 11 and FIG. 12, in the power cord according to some embodiments of the present disclosure, the power cord further includes a first return wire 300 and a second return wire 400 located in the fifth insulation layer 500. One end of the first return wire 300 adjacent to the output end is connected to the second terminal. One end of the second return wire 400 adjacent to the output end is connected to the fifth terminal.

It shall be understood that through the arrangement of the first return wire 300, an electrical signal on the first shielding conductor structure 130 transmitted from the second terminal can be guided back from the side adjacent to the output end of the power cord to the side adjacent to the input end of the power cord. Similarly, through the arrangement of the second return wire 400, an electrical signal on the second shielding conductor structure 230 transmitted from the fifth terminal can be guided back from the side adjacent to the output end of the power cord to the side adjacent to the input end of the power cord. As such, a detection protection device for the power cord may be arranged only at the side adjacent to the input end of the power cord to provide leakage detection of the power cord and open-circuit detection of the shield structures.

Referring to FIG. 11 and FIG. 12, in the power cord according to some embodiments of the present disclosure, the first shielding conductor structure 130 further includes a second shield layer 133 wrapping the first shield layer 131 and the first conductor 132, and the first conductor 132 is located between the first shield layer 131 and the second shield layer 133; and the second shielding conductor structure 230 further includes a fourth shield layer 233 wrapping the third shield layer 231 and the second conductor 232, and the second conductor 232 is located between the third shield layer 231 and the fourth shield layer 233.

It shall be understood that the scheme described in this embodiment is based on a scheme in which the first return wire 300 and the second return wire 400 are arranged in the fifth insulation layer 500, and for its specific functions and effects, reference can be made to the above schemes in which the arrangement of the first return wire 300 and the second return wire 400 in the fifth insulation layer 500 is not described, and the details will not be repeated herein.

In the power cord according to some embodiments of the present disclosure, the first shield layer 131 is made of a single-sided-conductive flexible material, the first shield layer 131 has an insulation surface facing inward and in contact with a surface of the outer side of the first insulation layer 120, and a conductive surface facing outward and in contact with the first conductor 132 and the second shield layer 133; the second shield layer 133 is a mesh woven from a plurality of strands of conductors to wrap the first shield layer 131; the third shield layer 231 is made of a single-sided-conductive flexible material, the third shield layer 231 has an insulation surface facing inward and in contact with a surface of an outer side of the third insulation layer 220, and a conductive surface facing outward and in contact with the second conductor 232 and the fourth shield layer 233; and the fourth shield layer 233 is a mesh woven from a plurality of strands of conductors to wrap the third shield layer 231.

It shall be understood that the scheme described in this embodiment is based on a scheme in which the first return wire 300 and the second return wire 400 are arranged in the fifth insulation layer 500, and for its specific functions and effects, reference can be made to the above schemes in which the arrangement of the first return wire 300 and the second return wire 400 in the fifth insulation layer 500 is not described, and the details will not be repeated herein.

In the power cord according to some embodiments of the present disclosure, the first return wire 300 may be located outside the first current-carrying wire 100, for example, as shown in FIG. 11; or the first return wire 300 may be located between the second insulation layer 140 and the first shielding conductor structure 130; or the first return wire 300 may be located in the first shielding conductor structure 130; or the first return wire 300 may be located between the first shielding conductor structure 130 and the first insulation layer 120.

When the first return wire 300 is adjacent to the first shielding conductor structure 130 or is located in the first shielding conductor structure 130, the first return wire 300 should be a lead wire having an insulation cover in order to prevent an electrical signal transmitted on the first return wire 300 from interfering with an electrical signal on the first shielding conductor structure 130.

In the power cord according to some embodiments of the present disclosure, the second return wire 400 may be located outside the second current-carrying wire 200, for example, as shown in FIG. 11; or the second return wire 400 may be located between the fourth insulation layer 240 and the second shielding conductor structure 230; or the second return wire 400 may be located in the second shielding conductor structure 230; or the second return wire 400 may be located between the second shielding conductor structure 230 and the third insulation layer 220.

Similarly, when the second return wire 400 is adjacent to the second shielding conductor structure 230 or is located in the second shielding conductor structure 230, the second return wire 400 should be a lead wire having an insulation cover in order to prevent an electrical signal transmitted on the second return wire 400 from interfering with an electrical signal on the second shielding conductor structure 230.

In the power cord according to some embodiments of the present disclosure, one end of the first shield layer 131 adjacent to the output end, one end of the first conductor 132 adjacent to the output end, or one end of the second shield layer 133 adjacent to the output end serves as the second terminal and is connected to one end of the first return wire 300 adjacent to the output end of the power cord.

It shall be understood that because the first shielding conductor structure 130 includes the first shield layer 131, the first conductor 132, and the second shield layer 133, all of which are electrically conductive, the second terminal may be led out from any one of the first shield layer 131, the first conductor 132, and the second shield layer 133 and connected to the first return wire 300.

In the power cord according to some embodiments of the present disclosure, one end of the third shield layer 231 adjacent to the output end, one end of the second conductor 232 adjacent to the output end, or one end of the fourth shield layer 233 adjacent to the output end serves as the fifth terminal and is connected to one end of the second return wire 400 adjacent to the output end of the power cord.

It shall be understood that because the second shielding conductor structure 230 includes the third shield layer 231, the second conductor 232, and the fourth shield layer 233, all of which are electrically conductive, the second terminal may be led out from any one of the third shield layer 231, the second conductor 232, and the fourth shield layer 233 and connected to the second return wire 400.

In the power cord according to some embodiments of the present disclosure, the first return wire 300 and the second return wire 400 are each a lead wire having an insulation cover.

In this embodiment, the first return wire 300 and the second return wire 400 are each a lead wire having an insulation cover, which can prevent an electrical signal transmitted on the first return wire 300 and an electrical signal transmitted on the second return wire 400 from interfering with other electrical signals.

In addition, in accordance with the second aspect of the present disclosure, an embodiment provides a power cord, which includes a first current-carrying wire 100 and a second current-carrying wire 200.

The first current-carrying wire 100 includes a first current-carrying conductor 110, a first insulation layer 120 wrapping the first current-carrying conductor 110, and a first shielding conductor structure 130. The first shielding conductor structure 130 is configured to detect a leakage current from the first current-carrying conductor 110. The first shielding conductor structure 130 includes a first shield layer 131 wrapping the first insulation layer 120. The first shielding conductor structure 130 has a first terminal adjacent to an input end of the power cord, a second terminal adjacent to an output end of the power cord, and a third terminal disposed between the first terminal and the second terminal.

The second current-carrying wire 200 includes a second current-carrying conductor 210, a third insulation layer 220 wrapping the second current-carrying conductor 210, and a second shielding conductor structure 230. The second shielding conductor structure 230 is configured to detect a leakage current from the second current-carrying conductor 210. The second shielding conductor structure 230 includes a third shield layer 231 wrapping the third insulation layer 220. The second shielding conductor structure 230 includes a fourth terminal adjacent to the input end, a fifth terminal adjacent to the output end, and a sixth terminal disposed between the fourth terminal and the fifth terminal.

The fifth insulation layer 500 encloses the first current-carrying wire 100 and the second current-carrying wire 200.

The first shielding conductor structure 130 and the second shielding conductor structure 230 are separated from each other in the fifth insulation layer 500, so that the first shielding conductor structure 130 is insulated from the second shielding conductor structure 230.

The first current-carrying wire 100 and the second current-carrying wire 200 further satisfy any one of the following four cases:
case one: the first current-carrying wire 100 further includes a first metal conductor 150 led out from the third terminal, and the first metal conductor 150 is connected to the sixth terminal,
case two: the second current-carrying wire 200 further includes a second metal conductor 250 led out from the sixth terminal, and the second metal conductor 250 is connected to the third terminal,
case three: the first current-carrying wire 100 further includes a first metal conductor 150 led out from the third terminal, the second current-carrying wire 200 further includes a second metal conductor 250 led out from the sixth terminal, and the first metal conductor 150 is connected to the second metal conductor 250.
case four: the power cord further includes a third metal conductor 900, and two terminals of the third metal conductor 900 are respectively connected to the third terminal and the sixth terminal.

It shall be understood that the power cord provided in this embodiment is the same as those in the above embodiments, except that in this embodiment, the first shielding conductor structure 130 does not include the first conductor 132, and the second shielding conductor structure 230 does not include the second conductor 232. In other words, a schematic diagram of the power cord of this embodiment can be obtained by removing the first conductor 132 and the second conductor 232 in FIG. 9A, FIG. 9B, FIG. 9C, and FIG. 9D.

According to the power cord provided by the embodiment of the present disclosure, when any one of the case one to the case four is satisfied, the third terminal of the first shielding conductor structure 130 and the sixth terminal of the second shielding conductor structure 230 in the power cord are electrically connected together, an association point is formed between the shielding conductor structures of the first current-carrying wire 100 and the second current-carrying wire 200, and the two shielding conductor structures are no longer independent of each other. For example, the first segment of the first shielding conductor structure 130 between the first terminal on the left side and the third terminal in the middle is electrically connected to the two segments of the second shielding conductor structure 230 by the first metal conductor 150 and/or the second metal conductor 250. Similarly, the second segment of the first shielding conductor structure 130 between the third terminal in the middle and the second terminal on the right side is electrically connected to the two segments of the second shielding conductor structure 230 by the first metal conductor 150 and/or the second metal conductor 250. As such, the first shielding conductor structure 130 and the second shielding conductor structure 230 form a shield network having a plurality of detection segments and capable of constructing a plurality of different detection choices, thereby greatly improving the feasibility and flexibility of leakage detection of the power cord and open-circuit detection of the shield structures, and improving the power supply safety of the power cord.

It can also be understood that the first shielding conductor structure 130 and the second shielding conductor structure 230 are separated from each other in the fifth insulation layer 500, so that the first shielding conductor structure 130 is insulated from the second shielding conductor structure 230, thereby preventing leakage detection of the first current-carrying wire 100 and leakage detection of the second current-carrying wire 200 from interfering with each other.

Referring to FIG. 13, in accordance with a third aspect of the present disclosure, an embodiment provides an electrical connection device 800, including a housing 810, a detection protection device arranged in the housing 810, and the power cord of any one of the embodiments of the second aspect. The first current-carrying conductor 110, the second current-carrying conductor 210, the first terminal, the second terminal, the fourth terminal, and the fifth terminal are connected to the detection protection device. The first terminal and the fourth terminal are located in the housing 810. The third terminal and the sixth terminal are located at a position where the power cord is connected to the housing 810.

Referring to FIG. 13, in accordance with the third aspect of the present disclosure, another embodiment provides an electrical connection device 800, including a housing 810, a detection protection device arranged in the housing 810, and the power cord of any one of the embodiments of the second aspect. The first current-carrying conductor 110, the second current-carrying conductor 210, the first terminal, the second terminal, the fourth terminal, and the fifth terminal are connected to the detection protection device. The first terminal and the fourth terminal are located in the housing 810. An output end of the power cord is configured to connect to a load device. The third terminal and the sixth terminal are located at a position where the power cord is connected to the load device.

Referring to FIG. 13, in accordance with the third aspect of the present disclosure, an embodiment further provides an electrical connection device 800, including a housing 810, a detection protection device arranged in the housing 810, and the power cord of any one of the embodiments of the second aspect. The first current-carrying conductor 110, the second current-carrying conductor 210, the first terminal, the second terminal, the fourth terminal, and the fifth terminal are connected to the detection protection device. The first terminal and the fourth terminal are located in the housing 810. An output end of the power cord is configured to connect to a load device. The third terminal and the sixth terminal are located between the housing 810 and the load device.

In the electrical connection device 800 according to some embodiments of the present disclosure, a clip configured to secure the power cord is arranged at a position where the power cord is connected to the housing 810.

The arrangement of the clip to secure the power cord can prevent the power cord from being easily dragged by an external force to detach the ports connected to the detection protection device.

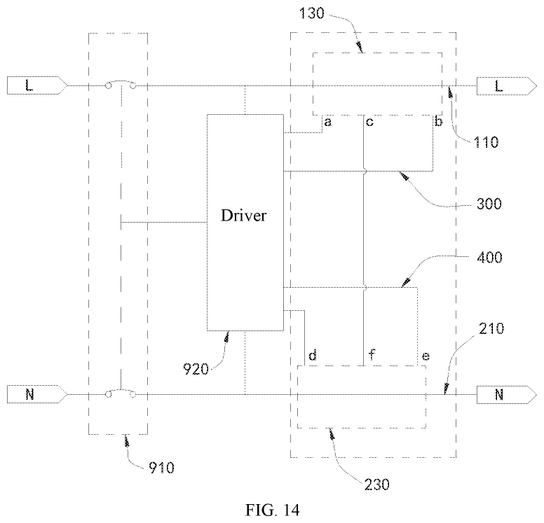

Referring to FIG. 14, in the electrical connection device 800 according to some embodiments of the present disclosure, the detection protection device includes:
a switch 910, configured to control a power connection between an input end and an output end of the power cord; and
a driver 920, respectively connected to the first current-carrying conductor 110, the second current-carrying conductor 210, the first terminal, the second terminal, the fourth terminal, the fifth terminal, and the switch 910, and configured to control the switch 910 to interrupt the power connection when a leakage current or an open circuit occurs in the first shielding conductor structure 130 and/or a leakage current or an open circuit occurs in the second shielding conductor structure 230.

It should be noted that in this embodiment, because the third terminal of the first shielding conductor structure 130 and the sixth terminal of the second shielding conductor structure 230 in the power cord are electrically connected together, an association point is formed between the shielding conductor structures of the first current-carrying wire 100 and the second current-carrying wire 200, and the two shielding conductor structures are no longer independent of each other. For example, the first segment of the first shielding conductor structure 130 between the first terminal on the left side and the third terminal in the middle is electrically connected to the two segments of the second shielding conductor structure 230 by the first metal conductor 150 and the second metal conductor 250. Similarly, the second segment of the first shielding conductor structure 130 between the third terminal in the middle and the second terminal on the right side is electrically connected to the two segments of the second shielding conductor structure 230 by the first metal conductor 150 and the second metal conductor 250. As such, the first shielding conductor structure 130 and the second shielding conductor structure 230 form a shield network having a plurality of detection segments and capable of constructing a plurality of different detection choices, thereby greatly improving the feasibility and flexibility of leakage detection of the power cord and open-circuit detection of the shield structures, and improving the power supply safety.

In addition, in accordance with a fourth aspect of the present disclosure, an embodiment provides an electrical device, including a load device and the electrical connection device of any one of the embodiments of the third aspect, where an output end of the power cord is connected to the load device.

In the electrical device of this embodiment, the third terminal of the first shielding conductor structure 130 and the sixth terminal of the second shielding conductor structure 230 in the power cord are electrically connected together, an association point is formed between the shielding conductor structures of the first current-carrying wire 100 and the second current-carrying wire 200, and the two shielding conductor structures are no longer independent of each other. For example, the first segment of the first shielding conductor structure 130 between the first terminal on the left side and the third terminal in the middle is electrically connected to the two segments of the second shielding conductor structure 230 by the first metal conductor 150 and the second metal conductor 250. Similarly, the second segment of the first shielding conductor structure 130 between the third terminal in the middle and the second terminal on the right side is electrically connected to the two segments of the second shielding conductor structure 230 by the first metal conductor 150 and the second metal conductor 250. As such, the first shielding conductor structure 130 and the second shielding conductor structure 230 form a shield network having a plurality of detection segments and capable of constructing a plurality of different detection choices, thereby greatly improving the feasibility and flexibility of leakage detection of the power cord and open-circuit detection of the shield structures, and improving the power supply safety of the power cord.

The embodiments of the present disclosure have been described in detail above with reference to the accompanying drawings, but the present disclosure is not limited to the above embodiments, and various changes may be made within the knowledge of those having ordinary skills in the art without departing from the scope of the present disclosure.

What is claimed is:

1. A current-carrying wire comprising:
a current-carrying conductor;
a first insulation layer, wrapping the current-carrying conductor;
a shielding conductor structure, configured to detect a leakage current from the current-carrying conductor, the shielding conductor structure including a shield layer wrapping the first insulation layer; and
a second insulation layer, wrapping the shielding conductor structure.

2. The current-carrying wire of claim 1, wherein the shielding conductor structure further includes a conductor in direct contact with the shield layer, the conductor being configured to transmit an electrical signal from the shielding conductor structure to outside of the current-carrying wire.

3. The current-carrying wire of claim 2, wherein the conductor is located between the first insulation layer and the shield layer, or located between the shield layer and the second insulation layer.

4. The current-carrying wire of claim 1, wherein:
the shield layer is made of a single-sided-conductive flexible material; and
the shield layer is helically wound around the first insulation layer, or wraps the first insulation layer in a direction parallel to an axial direction of the current-carrying conductor.

5. The current-carrying wire of claim 1, wherein:
the shield layer includes a mesh of a plurality of strands of conductors; or
the shield layer includes a single-sided-conductive flexible material and a mesh of a plurality of strands of conductors.

6. The current-carrying wire of claim 1, further comprising:
a metal conductor;
wherein:
the shielding conductor structure has a first terminal adjacent to an input end of the current-carrying conductor, a second terminal adjacent to an output end of the first current-carrying conductor, and a third terminal disposed between the first terminal and the second terminal; and
the metal conductor is led out from the third terminal, and the second insulation layer has an opening through which the metal conductor passes.

7. The current-carrying wire according to claim 1, wherein:
the shield layer is a first shield layer;
the shielding conductor structure further includes:
a second shield layer wrapping the first shield layer; and
a conductor located between the first shield layer and the second shield layer, the conductor being configured to transmit an electrical signal from the shielding conductor structure to outside of the current-carrying wire.

8. The current-carrying wire of claim 7, wherein:
the first shield layer is made of a single-sided-conductive flexible material, and the second shield layer includes a mesh of a plurality of strands of conductors, an insulation surface of the first shield layer facing inward and being in contact with a surface of an outer side of the first insulation layer, and a conductive surface of the first shield layer facing outward and being in contact with the conductor and the second shield layer; or
the first shield layer includes a mesh of a plurality of strands of conductors, and the second shield layer is made of a single-sided-conductive flexible material, a conductive surface of the second shield layer facing inward and being in contact with the conductor and the first shield layer, and an insulation surface of the second shield layer facing outward and being in contact with a surface of an inner side of the second insulation layer.

9. A power cord comprising:
a first current-carrying wire, including a first current-carrying conductor, a first insulation layer wrapping the first current-carrying conductor, and a first shielding conductor structure configured to detect a leakage current from the first current-carrying conductor, the first shielding conductor structure including a first shield layer wrapping the first insulation layer;
a second current-carrying wire, including a second current-carrying conductor, a third insulation layer wrapping the second current-carrying conductor, and a second shielding conductor structure configured to detect a leakage current from the second current-carrying conductor, the second shielding conductor structure including a third shield layer wrapping the third insulation layer; and
a fifth insulation layer, enclosing the first current-carrying wire and the second current-carrying wire;
wherein the first shielding conductor structure and the second shielding conductor structure are separated from each other in the fifth insulation layer, and are insulated from each other.

10. The power cord according to claim 9,
wherein the first shielding conductor structure has a first terminal adjacent to an input end of the power cord, a second terminal adjacent to an output end of the power cord, and a third terminal disposed between the first terminal and the second terminal;
wherein the second shielding conductor structure has a fourth terminal adjacent to the input end, a fifth terminal adjacent to the output end, and a sixth terminal disposed between the fourth terminal and the fifth terminal; and
wherein:
the first current-carrying wire further includes a first metal conductor led out from the third terminal and connected to the sixth terminal;
the second current-carrying wire further includes a second metal conductor led out from the sixth terminal and connected to the third terminal;
the first current-carrying wire further includes the first metal conductor led out from the third terminal, the second current-carrying wire further includes the second metal conductor led out from the sixth terminal, and the first metal conductor is connected to the second metal conductor; or
the power cord further includes a third metal conductor, and two terminals of the third metal conductor are respectively connected to the third terminal and the sixth terminal.

11. The power cord according to claim 9, wherein:
the first shielding conductor structure further includes a first conductor in direct contact with the first shield layer, and the first conductor is configured to transmit an electrical signal from the first shielding conductor structure to outside of the current-carrying wire; and
the second shielding conductor structure further includes a second conductor in direct contact with the third shield layer, and the second conductor is configured to transmit an electrical signal from the second shielding conductor structure to outside of the current-carrying wire.

12. The power cord of claim 11, wherein:
the first current-carrying wire further includes a second insulation layer wrapping the first shielding conductor structure; and/or
the second current-carrying wire further includes a fourth insulation layer wrapping the second shielding conductor structure.

13. The power cord of claim 9, wherein space in the fifth insulation layer not occupied by the first current-carrying wire and the second current-carrying wire is filled with an insulation material.

14. The power cord of claim 9, wherein:
wherein the first shielding conductor structure has a first terminal adjacent to an input end of the power cord, a second terminal adjacent to an output end of the power cord, and a third terminal disposed between the first terminal and the second terminal;
wherein the second shielding conductor structure has a fourth terminal adjacent to the input end, a fifth terminal adjacent to the output end, and a sixth terminal disposed between the fourth terminal and the fifth terminal; and
wherein:
the first current-carrying wire further includes a first metal conductor led out from the third terminal and a second insulation layer wrapping the first shielding conductor structure, and the second insulation layer has a first opening through which the first metal conductor passes; and/or
the second current-carrying wire further includes a second metal conductor led out from the sixth terminal and a fourth insulation layer wrapping the second shielding conductor structure, and the fourth insulation layer has a second opening through which the second metal conductor passes.

15. The power cord of claim 9,
wherein the first shielding conductor structure has a first terminal adjacent to an input end of the power cord, a second terminal adjacent to an output end of the power cord, and a third terminal disposed between the first terminal and the second terminal;
wherein the second shielding conductor structure has a fourth terminal adjacent to the input end, a fifth terminal adjacent to the output end, and a sixth terminal disposed between the fourth terminal and the fifth terminal; and
wherein:
the first current-carrying wire further includes a first metal conductor led out from the third terminal and soldered to the sixth terminal;
the second current-carrying wire further includes a second metal conductor led out from the sixth terminal and soldered to the third terminal;
the first current-carrying wire further includes the first metal conductor led out from the third terminal, the second current-carrying wire further includes the second metal conductor led out from the sixth terminal, and the first metal conductor and the second metal conductor are electrically connected by soldering at a position between the third terminal and the sixth terminal; or
the power cord further includes a third metal conductor, and two terminals of the third metal conductor are respectively soldered to the third terminal and the sixth terminal.

16. The power cord of claim 9,
wherein the first shielding conductor structure further includes a first conductor in direct contact with the first shield layer, and the first conductor is configured to transmit an electrical signal from the first shielding conductor structure to outside of the current-carrying wire;
wherein the second shielding conductor structure further includes a second conductor in direct contact with the third shield layer, and the second conductor is configured to transmit an electrical signal from the second shielding conductor structure to outside of the current-carrying wire;
wherein the first shielding conductor structure has a first terminal adjacent to an input end of the power cord, a second terminal adjacent to an output end of the power cord, and a third terminal disposed between the first terminal and the second terminal;
wherein the second shielding conductor structure has a fourth terminal adjacent to the input end, a fifth terminal adjacent to the output end, and a sixth terminal disposed between the fourth terminal and the fifth terminal;
wherein the first current-carrying wire further includes a first metal conductor led out from the third terminal, and the second current-carrying wire further includes a second metal conductor led out from the sixth terminal; and
wherein:
the first metal conductor and the second metal conductor extend to a position adjacent to the input end or extend to a position adjacent to the output end to achieve an electrical connection;
the first conductor and the second conductor each include a multi-strand wire, the first metal conductor is formed by at least one strand in the first conductor led out from the third terminal, and the second metal conductor is formed by at least one strand in the second conductor led out from the sixth terminal; or
the first shield layer includes a mesh of a plurality of strands of conductors, and the third shield layer includes a mesh of a plurality of strands of conductors, the first metal conductor is formed by at least one strand of conductor in the first shield layer led out from the third terminal, and the second metal conductor is formed by at least one strand of conductor in the third shield layer led out from the sixth terminal.

17. The power cord of claim 9, further comprising:
a first return wire and a second return wire located in the fifth insulation layer;
wherein:
the first shielding conductor structure has a first terminal adjacent to an input end of the power cord, a second terminal adjacent to an output end of the power cord, and a third terminal disposed between the first terminal and the second terminal;
the second shielding conductor structure has a fourth terminal adjacent to the input end, a fifth terminal adjacent to the output end, and a sixth terminal disposed between the fourth terminal and the fifth terminal; and
one end of the first return wire adjacent to the output end is connected to the second terminal, and one end of the second return wire adjacent to the output end is connected to the fifth terminal.

18. The power cord of claim 17, wherein:
the first return wire is located outside the first current-carrying wire; or
the first current-carrying wire further includes a second insulation layer wrapping the first shielding conductor structure, and the first return wire is located between the second insulation layer and the first shielding conductor structure; or
the first return wire is located in the first shielding conductor structure; or
the first return wire is located between the first shielding conductor structure and the first insulation layer.

19. An electrical connection device comprising:
a housing;
a detection protection device arranged in the housing; and
a power cord including:
a first current-carrying wire, including a first current-carrying conductor, a first insulation layer wrapping the first current-carrying conductor, and a first shielding conductor structure configured to detect a leakage current from the first current-carrying conductor, the first shielding conductor structure including a first shield layer wrapping the first insulation layer;
a second current-carrying wire, including a second current-carrying conductor, a third insulation layer wrapping the second current-carrying conductor, and a second shielding conductor structure configured to detect a leakage current from the second current-carrying conductor, the second shielding conductor structure including a third shield layer wrapping the third insulation layer; and
a fifth insulation layer, enclosing the first current-carrying wire and the second current-carrying wire;
wherein the first shielding conductor structure and the second shielding conductor structure are separated from each other in the fifth insulation layer, and are insulated from each other;
wherein the first shielding conductor structure has a first terminal adjacent to an input end of the power cord, a second terminal adjacent to an output end of the power cord, and a third terminal disposed between the first terminal and the second terminal;
wherein the second shielding conductor structure has a fourth terminal adjacent to the input end, a fifth terminal adjacent to the output end, and a sixth terminal disposed between the fourth terminal and the fifth terminal;
wherein the first current-carrying conductor, the second current-carrying conductor, the first terminal, the second terminal, the fourth terminal, and the fifth terminal are connected to the detection protection device, the first terminal and the fourth terminal are located in the housing; and
wherein:
the third terminal and the sixth terminal are located at a position where the power cord is connected to the housing; or
an output end of the power cord is configured to connect to a load device, and the third terminal and the sixth terminal are located at a position where the power cord is connected to the load device or are located between the housing and the load device.

20. An electrical device comprising:
the load device; and
the electrical connection device of claim 19;
wherein the output end of the power cord is connected to the load device.
